(19) United States
(12) Patent Application Publication
(10) Pub. No.: US 2017/0309644 A1
(43) Pub. Date: Oct. 26, 2017

(54) DISPLAY DEVICE

(71) Applicant: HannStar Display Corporation, Taipei City (TW)

(72) Inventor: Cheng-Yen YEH, Taichung City (TW)

(21) Appl. No.: 15/166,248

(22) Filed: May 26, 2016

(30) Foreign Application Priority Data
Apr. 21, 2016 (CN) 201610251643.2

(51) Int. Cl. H01L 27/12

(52) U.S. Cl. CPC H01L 27/124; H01L 27/1218

(57) ABSTRACT

The display device includes a display area, a non-display area, pixel structures, gate lines, data lines, first fan-out conductive lines, second fan-out conductive lines and a driving circuit. The shape of the display area is non-rectangular. The pixel structures, the gate lines and the data lines are disposed in the display area. The first fan-out conductive lines are disposed in the non-display area, and are coupled to the gate lines. The second fan-out conductive lines are disposed in the non-display area, and are coupled to the data lines. The driving circuit is coupled to the first fan-out conductive lines and the second fan-out conductive lines. The first fan-out conductive lines and the second fan-out conductive lines are formed in at least three different conductive layers.

### RELATED APPLICATIONS

This application claims priority to China Application Serial Number 201610251643.2, filed Apr. 21, 2016, which is herein incorporated by reference.

### BACKGROUND

### Field of Invention

The present invention relates to a display device. More particularly, the present invention relates to the display device having a non-rectangular display area.

### Description of Related Art

In general, a display device has a display area and a non-display area. Pixel structures, gate lines and data lines are disposed in the display area. Fan-out conductive lines, which are coupled to the gate lines and the data lines, are disposed in the non-display area. The fan-out conductive lines are coupled to a driving chip to transmit gate signals and data signals to the gate lines and the data lines respectively. Because the fan-out conductive lines are disposed in the non-display area and are concentrated toward the driving chip, a border of the display device is required to accommodate more fan-out conductive lines nearby the driving chip. Recently, the resolution of the display device is increasing, and therefore the number of the fan-out conductive lines is also increasing. However, the demand for a narrow border is conversely increasing in the market. Therefore, it is an issue urgent to be solved to keep the width of the border the same or even less while the solution is increasing. In particular, how to meet the requirement of the narrow border for non-rectangular display devices (e.g. smart watch) is an issue concerned by people in the art.

### SUMMARY

An objective of the present disclosure is to provide a display device having a narrow border. Embodiments of the present disclosure provide a display device including a substrate, pixel structures, gate lines, data lines, first fan-out conductive lines, second fan-out conductive lines and at least one driving circuit. The display device has a display area and a non-display area, and a shape of the display area is non-rectangular. The pixel structures are disposed in the display area, and are arranged as pixel rows and pixel columns. The gate lines and the data lines are disposed in the display area. The gate lines are coupled to the pixel rows, and the data lines are coupled to the pixel columns. The first fan-out conductive lines are disposed in the non-display area, and are coupled to the gate lines. The second fan-out conductive lines disposed in the non-display area, and are coupled to the data lines. The driving circuit is coupled to the first fan-out conductive lines and the second fan-out conductive lines. The first fan-out conductive lines and the second fan-out conductive lines are formed in at least three different conductive layers.

In some embodiments, at least one of the first fan-out conductive lines belongs to a first conductive layer. Two adjacent ones of the second fan-out conductive lines are respectively belong to a second conductive layer and a third conductive layer. The first conductive layer, the second conductive layer and the third conductive layer are different from each other.

In some embodiments, the first conductive layer is a first metal layer, the second conductive layer is a second metal layer, and the third conductive layer is a third metal layer. The second metal layer is formed at a side of the first metal layer opposite to the substrate, and the third metal layer is formed at a side of the second metal layer opposite to the first metal layer. In some embodiments, the first conductive layer is the third metal layer, the second conductive layer is the first metal layer, and the third conductive layer is the second metal layer. In some embodiments, two adjacent ones of the first fan-out conductive lines are respectively belong to the third metal layer and a fourth metal layer. The fourth metal layer is formed at a side of the third metal layer opposite to the second metal layer.

In some embodiment, the driving circuit includes a gate driving circuit and a data driving circuit. At least one of the gate driving circuit and the data driving circuit is disposed in the non-display area. In some embodiment, the driving circuit is disposed on at least one flexible circuit board. The at least one flexible circuit board is connected to the first fan-out conductive lines and the second fan-out conductive lines.

In some embodiments, each of the gate lines is electrically connected to one of the pixel rows, and each of the data lines is electrically connected to one of the pixel columns. In some embodiments, two adjacent ones of the gate lines are electrically connected to one of the pixel rows, and each of the data lines is electrically connected to two adjacent ones of the pixel columns.

In some embodiment, the at least one driving circuit includes multiple gate driving circuits and a data driving circuit. The gate driving circuits are disposed in the non-display area. Each of the first fan-out conductive lines is electrically connected to one of the gate driving circuits. The second fan-out conductive lines are electrically connected to the data driving circuit.

In some embodiments, the at least one driving circuit includes multiple gate driving circuits and a data driving circuit. The gate driving circuits are disposed in the non-display area. Each of the first fan-out conductive lines is electrically connected to one of the gate driving circuits, and the second fan-out conductive lines are electrically connected to the data driving circuit.

In some embodiments, one of the pixel structures is partially disposed in the display area and partially disposed in the non-display area.

In some embodiments, at least one of the second fan-out conductive lines has a first portion belonging to the second metal layer and a second portion belonging to the third metal layer. An insulating layer is formed between the second metal layer and the third metal layer, and the insulating layer includes an opening exposing the first portion. The first portion and the second portion are electrically connected to each other through a conducting layer, and the conducting layer directly contacts the second portion and directly contacts the first portion through the opening.

In some embodiments, material of the conducting layer is transparent conductive material.

In some embodiments, another second fan-out conductive line adjacent to the at least one second fan-out conductive line includes a third portion and a fourth portion. Both of the third portion and the fourth portion belong to the second metal layer. The insulating layer includes a second opening to expose the third portion and a third opening to expose the fourth portion. The third portion is electrically connected to the fourth portion through the conducting layer. The conducting layer directly contacts the third portion through the second opening and directly contacts the fourth portion through the third opening.

In some embodiments, at least one of the second fan-out conductive lines includes a first portion belonging to the second metal layer and a second portion belonging to the third metal layer. An insulating layer is formed between the second metal layer and the third metal layer, and the insulating layer includes an opening exposing the first portion. The second portion is electrically connected to the first portion through the opening.

In some embodiments, at least one of the second fan-out conductive lines includes a first portion belonging to the second metal layer and a second portion belonging to the first metal layer. An insulating layer is formed between the second metal layer and the third metal layer, and the insulating layer includes an opening exposing the second portion. The first portion and the second portion are electrically connected to each other by a conducting layer, and the conducting layer directly contacts the first portion and directly contacts the second portion through the opening.

In some embodiments, at least one of the first fan-out conductive lines includes a first portion belonging to the first metal layer and a second portion belonging to the third metal layer. A first insulating layer and a second insulating layer are formed between the first metal layer and the third metal layer. The first insulating layer includes a first opening exposing the first portion, and the second insulating layer includes a second opening exposing the first opening. The first portion and the second portion are electrically connected to each other through a conducting layer, and the conducting layer directly contacts the second portion and directly contacts the first portion through the first opening and the second opening.

In some embodiments, at least one of the second fan-out conductive lines includes a first portion belonging to the second metal layer and a second portion belonging to the first metal layer. An insulating layer is formed between the first metal layer and the second metal layer, and the insulating layer includes an opening exposing the second portion. The first portion is electrically connected to the second portion through the opening.

In some embodiments, at least one of the first fan-out conductive lines includes a first portion belonging to the first metal layer and a second portion belonging to the third metal layer. A metal pad belonging to the second metal layer is formed between the first portion and the second portion. The first portion, the metal pad and the second portion are stacked on the substrate. The first portion, the metal pad and the second portion are electrically connected to each other.

Compared with prior art, the present disclosure has advantages of: the border of the display device is narrowed.

### BRIEF DESCRIPTION OF THE DRAWINGS

The invention can be more fully understood by reading the following detailed description of the embodiment, with reference made to the accompanying drawings as follows:

FIG. 1 is a diagram illustrating a top view of a display device according to a first embodiment.

FIG. 2 is a diagram illustrating an enlarged view of pixel structures P, gate lines GL(1)-GL(m) and data lines DL(1)-DL(n) in the display area 110 of FIG. 1.

FIG. 3 to FIG. 5 are diagrams illustrating cross-sectional views of the first fan-out conductive lines FGL(1)-FGL(m) and the second fan-out conductive lines FDL(1)-FDL(n) according to three different embodiments.

FIG. 6 is a schematic diagram illustrating a top view of a display device 200 according to a second embodiment.

FIG. 7 is a schematic diagram illustrating a top view of a display device 300 according to a third embodiment.

FIG. 8 is a schematic diagram illustrating a top view of a display device 400 according to a fourth embodiment.

FIG. 9 is a schematic diagram illustrating a top view of a display device 500 according to a fifth embodiment.

FIG. 10 is a schematic diagram illustrating a top view of a display device 600 according to a sixth embodiment.

FIG. 11 is a diagram illustrating an enlarged view of the pixel structures, the gate lines and the data lines in the display area 110 of FIG. 10.

FIG. 12a and FIG. 12b are schematic diagrams illustrating part of the display device having a circle-shape display area.

FIG. 13 is a diagram illustrating a cross-sectional view of a thin film transistor T in the pixel structure P according to the first embodiment to the sixth embodiment.

FIG. 14 and FIG. 15 are schematic diagrams illustrating the connection structures according to the first embodiment to the sixth embodiment.

FIG. 16 is a schematic diagram illustrating another connection structure according to the first embodiment to the sixth embodiment.

FIG. 17 is a schematic diagram illustrating a connection structure according to the first embodiment to the sixth embodiment.

FIG. 18 is a schematic diagram illustrating another connection structure according to the first embodiment to the sixth embodiment.

### DETAILED DESCRIPTION

The using of “first”, “second”, “third”, etc. in the specification should be understood for identifying units or data described by the same terminology, but are not referred to particular order or sequence. In other words, “first”, “second”, “third” and “fourth” may be exchanged. In addition, the term “couple” used in the specification should be understood for electrically connecting two units directly or indirectly. In other words, when “a first object is coupled to a second object” is written in the specification, it means another object may be disposed between the first object and the second object.

### First Embodiment

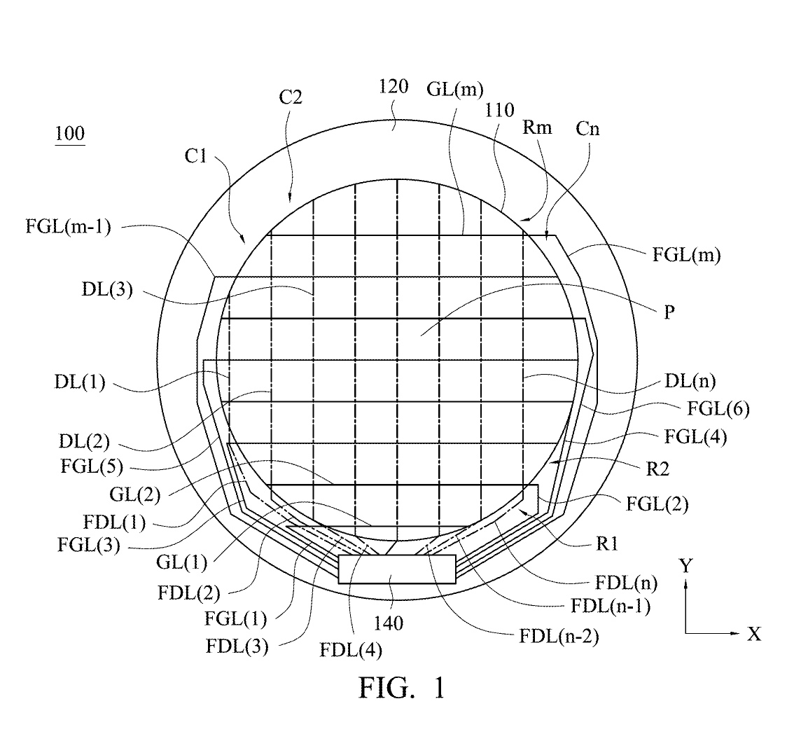

FIG. 1 is a diagram illustrating a top view of a display device according to a first embodiment. Referring to FIG. 1, a display device 100 has a display area 110 and a non-display area 120. A shape of the display area 110 is non-rectangular. In the embodiment, the display device 100 is implemented as a watch, but it may be implemented as other mobile devices, appliances, a dashboard, or any other electronic devices, and the invention is not limited thereto. In addition, the shape of the display area 110 is circular, but the shape of the non-rectangular display area may be oval, triangular, trapezoidal, heart-shaped or other irregular shapes. The shape of the non-rectangular in the disclosure is not limited to the aforementioned examples. The shape of the non-display area 120 and the shape of the display area 110 are both circular in the embodiment, but the shape of the non-display area 120 may be different from that of the display area 110 in other embodiments.

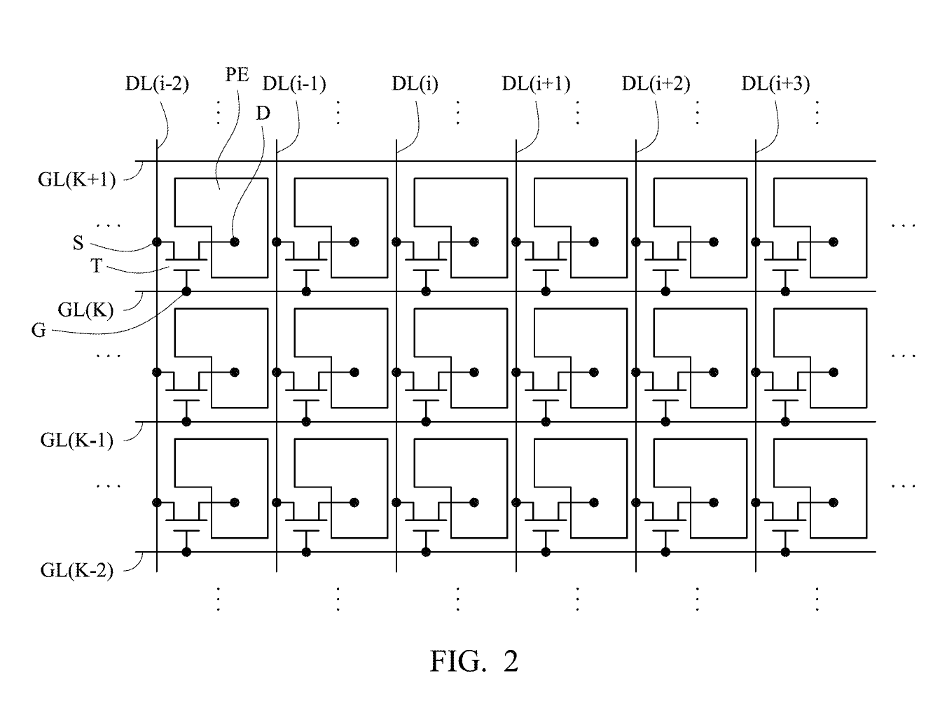

Multiple pixel structure P (only one pixel structure P is labled in FIG. 1 as an example) are disposed in the display area 110. The pixel structures P are disposed on a substrate, and are arranged as pixel rows R1-Rm and pixel columns C1-Cn. The display area 110 contains gate lines GL(1)-GL(m) and data lines DL(1)-DL(n). The gate lines GL(1)-GL(m) are electrically connected to the pixel structures P in the pixel rows R1-Rm respectively. The data lines DL(1)-DL(n) are electrically connected to the pixel structures P in the pixel columns C1-Cn respectively. Referring to FIG. 1 and FIG. 2, FIG. 2 is a diagram illustrating an enlarged view of the pixel structures P, the gate lines GL(1)-GL(m) and data lines DL(1)-DL(n) in the display area 110 of FIG. 1. Each pixel structure P includes a thin film transistor (TFT) T and a pixel electrode PE connected to the TFT T. A gate G and a source S of the TFT T are electrically connected to one of the gate lines GL(1)-GL(m) and one of the data lines DL(1)-DL(n) respectively, and a drain D is electrically connected to the pixel electrode PE. Referring to FIG. 1, first fan-out conductive lines FGL(1)-FGL(m), second fan-out conductive lines FDL(1)-FDL(n), and a driving circuit 140 are disposed in the non-display area 120. One end of each of the first fan-out conductive lines FGL(1)-FGL(m) is electrically connected to corresponding one of the gate lines GL(1)-GL(m) in the display area 110. The first fan-out conductive lines FGL(1)-FGL(m) extend toward the area of the driving circuit 140 so that the other end of each of the first fan-out conductive lines FGL(1)-FGL(m) is electrically connected to driving circuit 140. Similarly, one end of each of the second fan-out conductive lines FDL(1)-FDL(n) is electrically connected to the corresponding one of the data lines DL(1)-DL(n) in the display area 110. The data lines DL(1)-DL(n) extend toward the area of the driving circuit 140 so that the other end of each of the second fan-out conductive lines FDL(1)-FDL(n) is electrically connected to the driving circuit 140.

As shown in FIG. 1, because the shape of the display area 110 is non-rectangular, the display area 110 is shrinking along a direction (toward negative Y-axis in the embodiment) from the center of the display area 110 to the driving circuit 140. The gate lines GL(1)-GL(m) and the data lines DL(1)-DL(n) in the display area 110 extend toward X-axis and Y-axis respectively. Therefore, part of the first fan-out conductive lines are interlaced with part of the second fan-out conductive lines for the first fan-out conductive lines FGL(1)-FGL(m) and the second fan-out conductive lines FDL(1)-FDL(n) to concentrate toward the area of the driving circuit 140. For example, the first fan-out conductive line FGL(1) is interlaced with the second fan-out conductive lines FDL(1), FDL(2) and FDL(3) in the lower left corner of FIG. 1. At least part of the first fan-out conductive lines FGL(1)-FGL(m) and at least part of the second fan-out conductive lines FDL(1)-FDL(n) belong to different conductive layers to prevent the first fan-out conductive lines FGL(1)-FGL(m) from being shorted to the second fan-out conductive lines FDL(1)-FDL(n). Material of the conductive layer may be metal or other suitable conductive material.

In addition, as shown in FIG. 1, both of the first fan-out conductive lines FGL(1)-FGL(m) and the second fan-out conductive lines FDL(1)-FDL(n) extend toward the driving circuit 140, and the density of the fan-out conductive lines is increasing toward the driving circuit 140 (toward the negative Y-axis in the embodiment). That is, the non-display area 120 is required to accommodate more fan-out conductive lines toward the driving circuit 140, and therefore the width of the border is limited by the pitches of the fan-out conductive lines (e.g. the first fan-out conductive line and the second fan-out conductive lines).

Accordingly, if all of the second fan-out conductive lines FDL(1)-FDL(n) are formed in the same conductive layer, or all of the first fan-out conductive lines FGL(1)-FGL(m) are formed in the same conductive layer, the line widths of the fan-out conductive lines and the spacing between adjacent fan-out conductive lines cannot be decreased due to the limitation of the exposure, development, and etching abilities of machine in the industry in order to prevent the fan-out conductive lines from being broken or to prevent the adjacent fan-out conductive lines from being shorted. These reasons make the pitches of the fan-out conductive lines cannot be decreased, and it leads to a broad border. Therefore, in the embodiment, adjacent second fan-out conductive lines are formed in different conductive layers and/or adjacent first fan-out conductive lines are formed in different conductive layers. Accordingly, the spacing between the fan-out conductive lines can be decreased, and the requirement of the narrow border is met.

For example, according to the process ability of current technology, the pitch of the fan-out conductive lines is 7 micrometer (μm) if adjacent fan-out conductive lines are formed in the same metal layer (e.g. both in the first metal layer or both in the second metal layer). The pitch of the fan-out conductive lines is reduced to 4 μm if adjacent fan-out conductive lines are formed in different metal layers (e.g. in the first metal layer and in the second metal layer respectively, or in the second metal layer and in the third metal layer respectively).

As shown in FIG. 1, in the non-display area 120 close to the left-hand side of the driving circuit 140, the first fan-out conductive lines FGL(1), FGL(3) . . . FGL(m−1) are closely adjacent to each other for extending toward the driving circuit 140. In the non-display area 120 close to the right-hand side of the driving circuit 140, the first fan-out conductive lines FGL(2), FGL(4) . . . FGL(m) are closely adjacent to each other for extending toward the driving circuit 140. Therefore, two adjacent ones of the first fan-out conductive lines (e.g. FGL(1) and FGL(3), FGL(3) and FGL(5), FGL(2) and FGL(4), FGL(4) and FGL(6)) may belong to different conductive layers. In other words, two adjacent ones of the first fan-out conductive lines may be formed in different conductive layers.

Similarly, in the non-display area 120 dose to the upper-left side of the driving circuit 140, the second fan-out conductive lines FDL(1), FDL(2), FDL(3), and FDL(4) are closely adjacent to each other for extending toward the driving circuit 140. In the non-display area 120 close to the upper-right side of the driving circuit 140, the second fan-out conductive lines FDL(m−2), FDL(m−1), and FDL(m) are closely adjacent to each other for extending toward the driving circuit 140. Therefore, two adjacent ones of the second fan-out conductive lines (e.g. FDL(1) and FDL(2), FDL(2) and FDL(3), FDL(m−2) and FDL(m−1), FDL(m−1) and FDL(m)) may belong to different conductive layers.

Therefore, in order to prevent the first fan-out conductive lines FGL(1)-FGL(m) from being shorted to the second fan-out conductive lines FDL(1)-FDL(n), and to reduce the layout area of the fan-out conductive lines, at least part of the first fan-out conductive lines FGL(1)-FGL(m) and at least part of the second fan-out conductive lines FDL(1)-FDL(n) belong to different conductive layers in the invention. In other words, at least part of the first fan-out conductive lines FGL(1)-FGL(m) belongs to a conductive layer, and at least part of the second fan-out conductive lines FDL(1)-FDL(n) belongs to another conductive layer to prevent the first fan-out conductive lines FGL(1)-FGL(m) from being shorted to the second fan-out conductive lines FDL(1)-FDL(n). In addition, two adjacent ones of the second fan-out conductive lines and/or two adjacent ones of the first fan-out conductive lines belong to different conductive layers in order to reduce the pitches of the second fan-out conductive lines and/or the pitches of the first fan-out conductive lines, and thus the layout area of the fan-out conductive lines are reduced.

For example, in some embodiments, each of the first fan-out conductive lines FGL(1)-FGL(m) belongs to one conductive layer, and each of the second fan-out conductive lines FDL(1)-FDL(n) belongs to another conductive layer. However, the invention is not limited thereto. In other embodiments, part of the first fan-out conductive lines FGL(1)-FGL(m) belongs to one conductive layer, and part of the second fan-out conductive lines FDL(1)-FDL(n) belongs to another conductive layer. In addition, in some embodiments, every adjacent two of the first fan-out conductive lines FGL(1)-FGL(m) are formed in different conductive layers and/or every adjacent two of the second fan-out conductive lines FGL(1)-FGL(m) are formed in different conductive layer, and the invention is not limited thereto. In other embodiments, every adjacent two of part of the first fan-out conductive lines FGL(1)-FGL(m) are formed in different conductive layers and/or every adjacent two of part of the second fan-out conductive lines FGL(1)-FGL(m) are formed in different conductive layers. People in art should be able to adjust the layout design and the arrangement of the first fan-out conductive lines FGL(1)-FGL(m) and the second fan-out conductive lines FDL(1)-FDL(n) according to the width of the border and the location of the driving circuit.

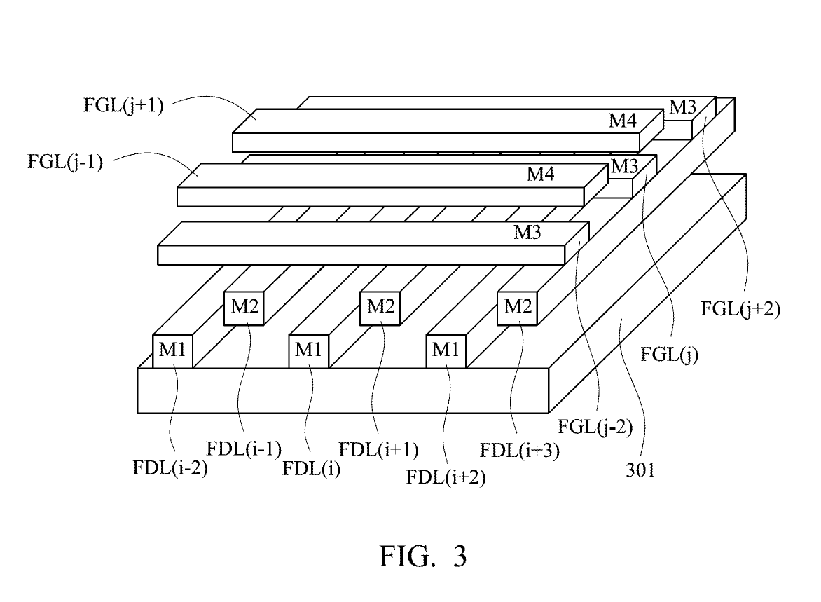

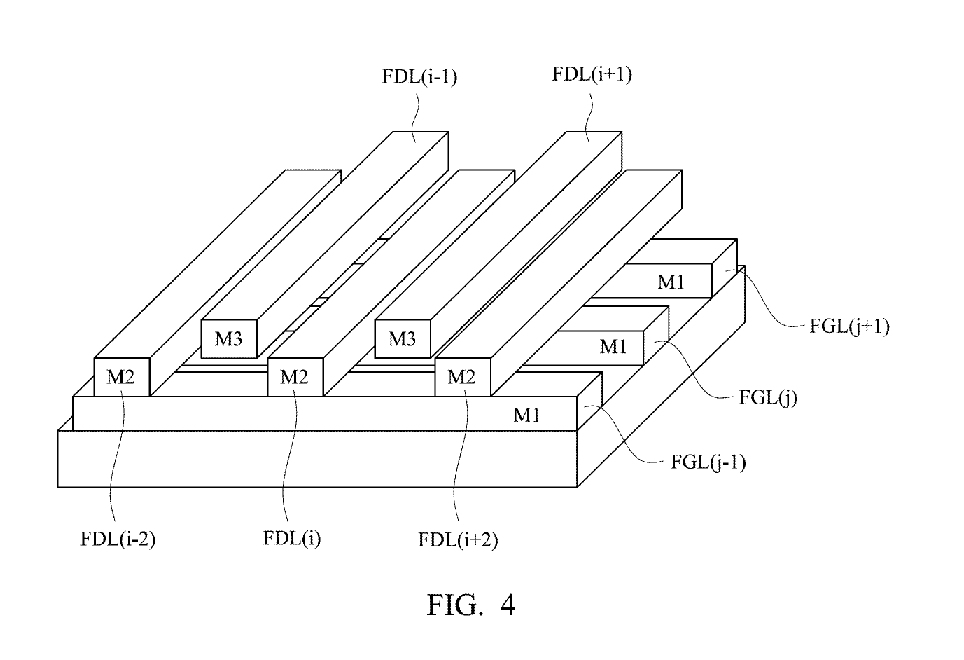

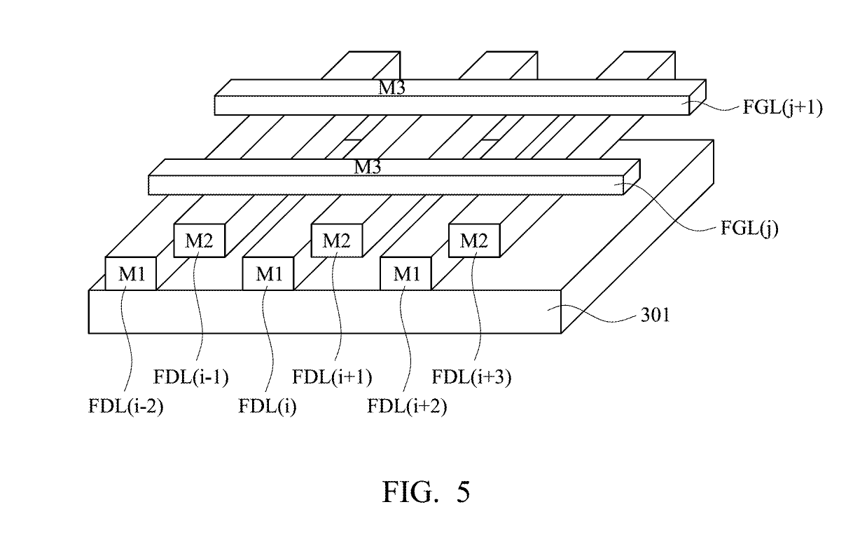

Referring to FIG. 3, FIG. 4 and FIG. 5, FIG. 3 to FIG. 5 are diagrams illustrating cross-sectional views of the first fan-out conductive line FGL(1)-FGL(m) and the second fan-out conductive line FDL(1)-FDL(n) according to three different embodiments, in which the cross-sectional views are corresponding to where the first fan-out conductive lines are interlaced with the second fan-out conductive lines in the non-display area 120. As shown in FIG. 3, the second fan-out conductive lines FDL(i−2), FDL(i) and FDL(i+2) belong to a first metal layer M1. The second fan-out conductive lines FDL(i−1), FDL(i+1) and FDL(i+3) belong to a second metal layer M2. The first fan-out conductive lines FGL(j−2), FGL(j) and FGL(j+2) belong to a third metal layer M3. The first fan-out conductive lines FGL(j−1) and FGL(j+1) belong to a fourth metal layer M4. The first metal layer M1, the second metal layer M2, the third metal layer M3 and the fourth metal layer M4 are sequentially formed on a substrate 301. Note that multiple insulating layers (not shown) are formed between the first metal layer M1 and the second metal layer M2, between the second metal layer M2 and the third metal layer M3, and between the third metal layer M3 and the fourth metal layer M4 respectively to prevent them from being shorted. In addition, although only the first fan-out conductive lines and the second fan-out conductive lines in the non-display area 120 are illustrated on the substrate 301 in FIG. 3, the pixel structures P in the display area 110 are also disposed on the substrate 301. In the embodiment of FIG. 3, the first fan-out conductive lines FGL(j−2)-FGL(j+2) and the second fan-out conductive lines FDL(i−2)-FDL(i+3) belong to different metal layers to prevent them from being shorted when they are interlaced. Besides, adjacent second fan-out conductive lines (e.g. FDL(i−2) and FDL(i−1), or FDL(i−1) and FDL(i)) belong to different metal layers, and adjacent first fan-out conductive lines (e.g. FGL(j−2) and FGL(j−1), or FGL(j−1) and FGL(j)) belong to different metal layers to reduce the pitches of the fan-out conductive lines, and thus the requirement of narrow border is met.

Note that although adjacent first fan-out conductive lines belong to the third metal layer M3 and fourth metal layer M4 respectively, and adjacent second fan-out conductive lines belong to the first metal layer M1 and the second metal layer M2 respectively in the embodiment of FIG. 3, it may be modified such that adjacent first fan-out conductive lines belong the first metal layer M1 and the second metal layer M2 respectively, and adjacent second fan-out conductive lines belong to the third metal layer M3 and the fourth metal layer M4 respectively in other embodiments.

Referring to FIG. 4, the first fan-out conductive lines FGL(j−1), FGL(j) and FGL(j+1) belong to the first metal layer M1. The second fan-out conductive lines FDL(i−2), FDL(i) and FDL(i+2) belong to the second metal layer M2. The second fan-out conductive lines FDL(i−1) and FDL(i+1) belong to the third metal layer M3. Referring to FIG. 5, the second fan-out conductive lines FDL(i−2), FDL(i) and FDL(i+2) belong to the first metal layer M1. The second fan-out conductive lines FDL(i−1), FDL(i+1) and FDL(i+3) belong to the second metal layer M2. The first fan-out conductive lines FGL(j) and FGL(j+1) belong to the third metal layer M3. In the embodiments of FIG. 4 and FIG. 5, the first fan-out conductive lines and the second fan-out conductive lines belong to different metal layers to prevent them from being shorted when they are interlaced. In addition, adjacent second fan-out conductive lines belong to different metal layers to reduce the spacing between the adjacent second fan-out conductive lines, and thus the width of the border is decreased. In FIG. 4 and FIG. 5, which is different from the embodiment of FIG. 3, the first fan-out conductive lines belong to the same metal layer, and therefore only three metal layers are used in the embodiments of FIG. 4 and FIG. 5 (four metal layers are used in the embodiment of FIG. 3), and thus the manufacturing cost of the display device may be decreased significantly. Although the first fan-out conductive lines belong to the same metal layer in FIG. 4 and FIG. 5, adjacent second fan-out conductive lines belong to different metal layers. Therefore, compared with the prior art in which the second fan-out conductive lines belong to the same metal layers, the embodiments of FIG. 4 and FIG. 5 still achieve narrow border and cost less than the embodiment of FIG. 3.

Note that although the first fan-out conductive lines belong to the first metal layer M1, and the adjacent second fan-out conductive lines belong to the second metal layer M2 and the third metal layer M3 respectively in the embodiment of FIG. 4, it may be modified such that the second fan-out conductive lines belong to the first metal layer M1, and the adjacent first fan-out conductive lines belong to the second metal layer M2 and the third metal layer M3 respectively in another embodiment.

Similarly, although adjacent second fan-out conductive lines belong to the first metal layer M1 and the second metal layer M2 respectively, and the first fan-out conductive lines belong to the third metal layer M3 in the embodiment of FIG. 5, it may be modified such that the adjacent first fan-out conductive lines belong to the first metal layer M1 and the second metal layer M2 respectively, and the second fan-out conductive lines belong to the third metal layer M3 in another embodiment.

To be specific, in the aforementioned embodiments, the first fan-out conductive lines FGL(1)-FGL(m) and the second fan-out conductive lines FDL(1)-FDL(n) in the non-display area 120 are formed in at least three different conductive layers in which at least one first fan-out conductive line belongs to the first conductive layer, and two adjacent second fan-out conductive lines belong to the second conductive layer and the third conductive layer respectively; or at least one second fan-out conductive line belongs to the first conductive layer, and two adjacent first fan-out conductive lines belong to the second conductive layer and the third conductive layer respectively; or two adjacent first fan-out conductive lines belong to the first conductive layer and the second conductive layer respectively, and two adjacent second fan-out conductive lines belong to the third conductive layer and the fourth conductive layer respectively. The first conductive layer, the second conductive layer, the third conductive layer and the fourth conductive layer are different from each other. The conductive layers may be metal layers or other suitable conductive layers. In addition, the sequence for forming these conductive layers is not limited in the invention. In other words, the first conductive layer may be formed between the second conductive layer and the third conductive layer, or the second conductive layer may be formed between the first conductive layer and third conductive layer, and so on.

Note that in the embodiment of FIG. 1, the driving circuit 140 includes a gate driving circuit and a data driving circuit. The gate driving circuit and the data driving circuit are disposed in the same chip, or the gate driving circuit and the data driving circuit are formed on a TFT array substrate of the display device 100. For example, transistors in the gate driving circuit and the data driving circuit and the TFTs T of the pixel structures P may be formed on the TFT array substrate at the same time by a low-temperature polysilicon process. In addition, although only one driving circuit 140 is illustrated in FIG. 1, the number of the driving circuit 140 is not limited in the invention.

### Second Embodiment

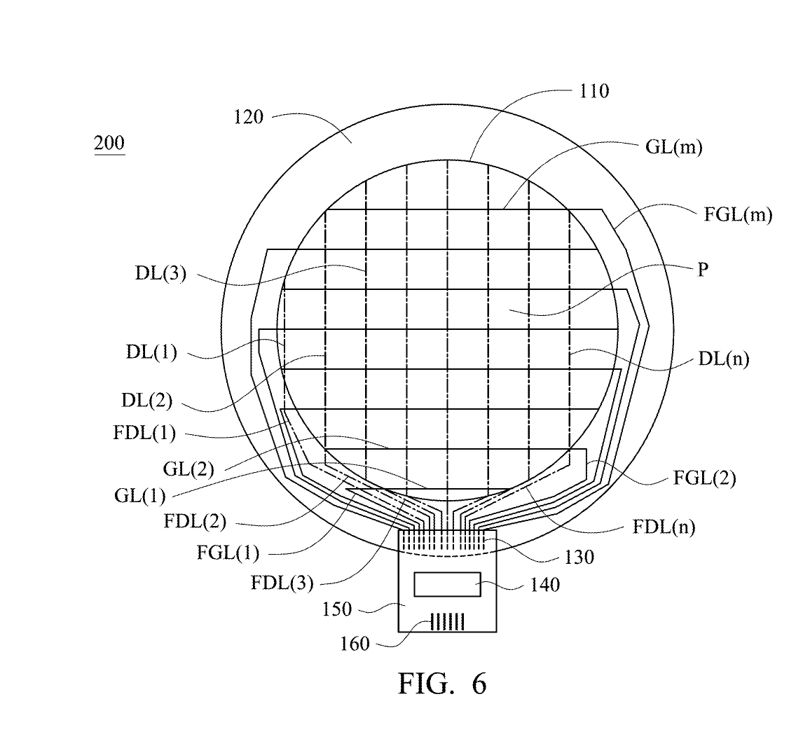

Referring to FIG. 6, FIG. 6 is a schematic diagram illustrating a top view of a display device 200 according to the second embodiment. The difference between FIG. 6 and FIG. 1 is that multiple bonding pads 130 are disposed in the non-display area 120 in FIG. 6. The bonding pads 130 are electrically connected to the first fan-out conductive lines FGL(1)-FGL(m) and the second fan-out conductive lines FDL(1)-FDL(n). The driving circuit 140 is disposed on a flexible circuit board 150 (e.g. Tape Carrier Package (TCP) or Chip on Film (COF)), and one side of the flexible circuit board 150 has multiple first bonding leads (show shown) electrically connected to the bonding pads 130, and the other side has multiple bonding leads 160 electrically connected to a circuit board (not shown). The flexible circuit board 150 has multiple conductive wires (not shown) to electrically connect the driving circuit 140 to the first bonding leads and the second bonding leads 160, and thus the driving circuit 140 is electrically connected to the bonding pads 130 and the circuit board, and the driving circuit 140 may provide gate signals and data signals to the pixel structures P in the display area 110. In the embodiment, the driving circuit 140 includes a gate driving circuit and a data driving circuit, and the gate driving circuit and the data driving circuit are disposed in the same chip.

Similar to the first embodiment, in the embodiment, at least part of the first fan-out conductive lines FGL(1)-FGL(m) and at least part of the second fan-out conductive lines FDL(1)-FDL(n) belong to different conductive layers, and adjacent second fan-out conductive lines and/or adjacent first fan-out conductive lines are formed in different conductive layers. That is, the first fan-out conductive lines FGL(1)-FGL(m) and the second fan-out conductive lines FDL(1)-FDL(n) are formed in at least three different conductive layers.

In addition, similar to the first embodiment, although only one driving circuit 140 is illustrated in FIG. 6, the number of the driving circuit 140 is not limited in the invention.

### Third Embodiment

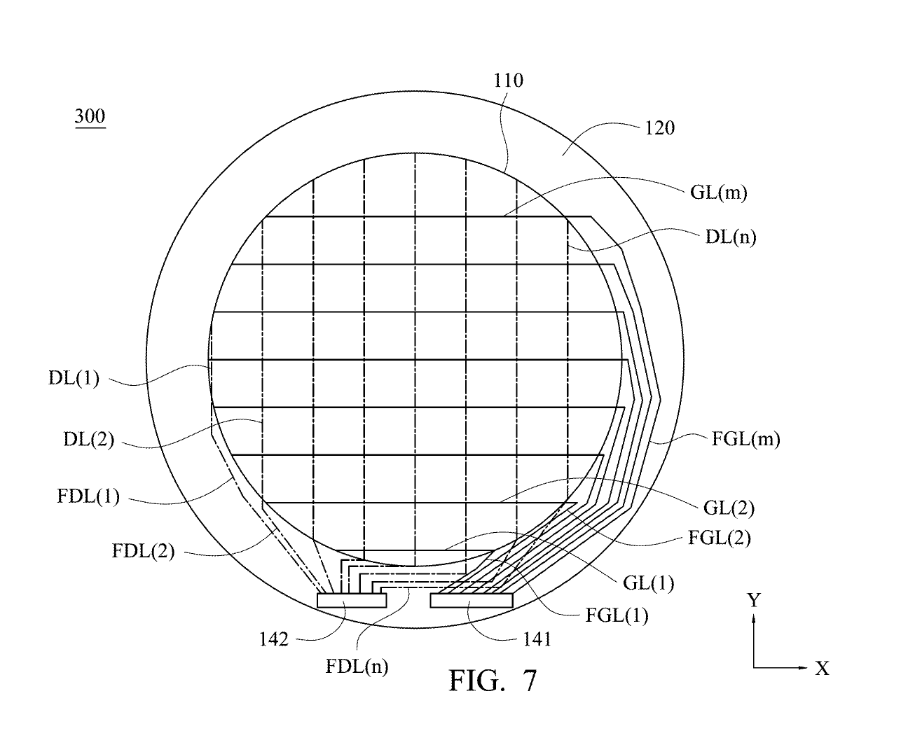

Referring to FIG. 7, FIG. 7 is a schematic diagram illustrating a top view of a display device 300 according to a third embodiment. The difference between FIG. 1 and FIG. 7 is that a gate driving circuit 141 and a data driving circuit 142 are disposed in the non-display area 120 in the embodiment of FIG. 7. Rest of FIG. 7 is similar to the embodiment of FIG. 1 and will not be repeated. Multiple first fan-out conductive lines FGL(1)-FGL(m) and second fan-out conductive lines FDL(1)-FDL(n) are disposed in the non-display area 120. Each of the first fan-out conductive lines FGL(1)-FGL(m) is coupled to one of the gate lines GL(1)-GL(m) and the gate driving circuit 141. Each of the second fan-out conductive lines FDL(1)-FDL(n) is coupled to one of the data lines DL(1)-DL(n) and the data driving circuit 142. The gate driving circuit 141 and the data driving circuit 142 may be implemented as a gate driving chip and a data driving chip respectively; or one of the gate driving circuit 141 and the data driving circuit 142 may be implemented as a chip, and the other driving circuit is formed on the TFT array substrate of the display device 300; or both the gate driving circuit 141 and the data driving circuit 142 may be formed on the TFT array substrate of the display device 300. Furthermore, only one gate driving circuit 141 and only one data driving circuit 142 are illustrated in FIG. 7, but the numbers of the gate driving circuit 141 and the data driving circuit 142 are not limited in the invention.

Similar to the first embodiment, in the embodiment, at least part of the first fan-out conductive lines FGL(1)-FGL(m) and at least part of the second fan-out conductive lines FDL(1)-FDL(n) belong to different conductive layers respectively, and adjacent second fan-out conductive lines and/or adjacent first fan-out conductive lines are formed in different conductive layers. That is, the first fan-out conductive lines FGL(1)-FGL(m) and the second fan-out conductive lines FDL(1)-FDL(n) are formed in at least three different conductive layers.

In addition, similar to the second embodiment, the gate driving circuit 141 and the data driving circuit 142 may be disposed on the same flexible circuit board or disposed on different flexible circuit boards in another embodiment. And, the non-display area 120 may have multiple bonding pads which are electrically connected to the first fan-out conductive lines FGL(1)-FGL(m) and the second fan-out conductive lines FDL(1)-FDL(n). The gate driving circuit 141 and the data driving circuit 142 are electrically connected to the bonding pads in the non-display area 120 through the bonding leads on the flexible circuit board. Therefore, the gate driving circuit 141 and the data driving circuit 142 may provide the gate signals and the data signals respectively to the pixel structures P in the display area 110.

### Fourth Embodiment

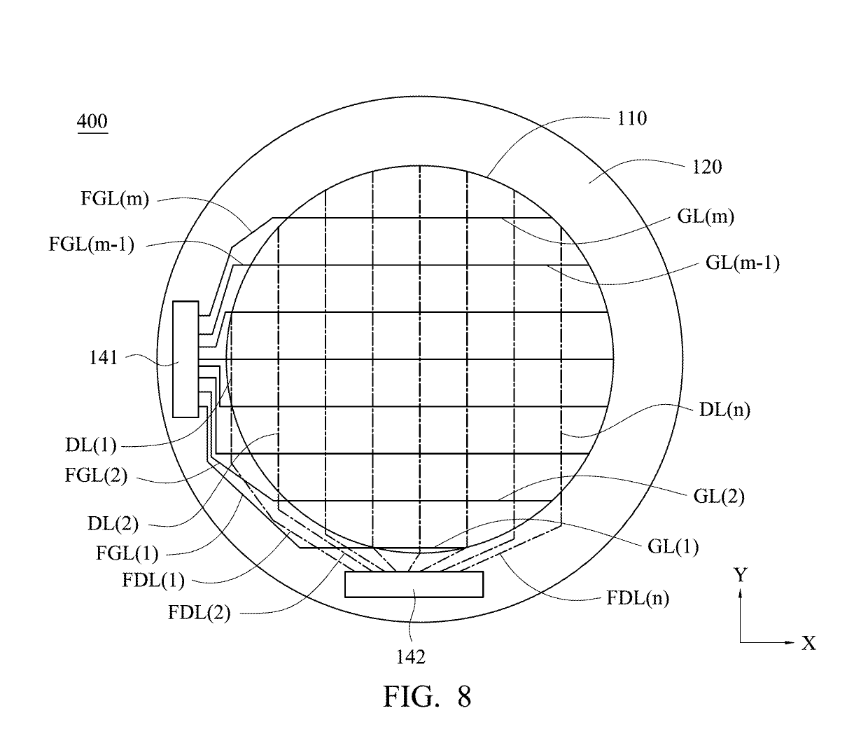

Referring to FIG. 8, FIG. 8 is a schematic diagram illustrating a top view of a display device 400 according to the fourth embodiment. The difference between FIG. 8 and FIG. 7 is that the gate driving circuit 141 and the data driving circuit 142 are disposed in the non-display area 120 below the display area 110 in the embodiment of FIG. 7, but the data driving circuit 142 is disposed in the non-display area 120 below the display area 110, and the gate driving circuit 141 is disposed in the non-display area 120 at the left-hand side of the display area 110 in the embodiment of FIG. 8. Because the gate lines GL(1)-GL(m) extend toward the X-axis and the gate driving circuit 141 is disposed below the display area 110 in FIG. 7, the first fan-out conductive lines FGL(1)-FGL(m) in FIG. 7 are electrically connected to the gate lines GL(1)-GL(m), pending toward the gate driving circuit 141 and concentrate at the area of the gate driving circuit 141. In addition, multiple parallel adjacent first fan-out conductive lines are coupled to the gate driving circuit 141 in the non-display area 120 close to the gate driving circuit 141. For example, there are m first fan-out conductive lines FGL(1)-FGL(m) which are tightly adjacent to each other near the gate driving circuit 141 in FIG. 7. Consequently, the non-display area 120 in FIG. 7 requires greater width. Compared to FIG. 7, the gate driving circuit 141 in FIG. 8 is disposed in the non-display area 120 at the left-hand side of the display area 110, and the gate lines GL(1)-GL(m) extends toward the X-axis. Therefore, the first fan-out conductive lines FGL(1)-FGL(m) may extend toward the gate driving circuit 141 from two opposite sides of the gate driving circuit 141. For example, the first fan-out conductive lines FGL(1) and FGL(2) extend toward the gate driving circuit 141 from one side of the gate driving circuit 141, and the first fan-out conductive lines FGL(m−1) and FGL(m) extend toward the gate driving circuit 141 from another side of the gate driving circuit 141. Accordingly, the requirement of the narrow border may be achieved more easily in the embodiment of FIG. 8 than in the embodiment of FIG. 7.

Similar to the embodiment of FIG. 7, the gate driving circuit 141 and the data driving circuit 142 in FIG. 8 may be implemented as a gate driving chip and a data driving chip respectively; or one of the gate driving circuit 141 and the data driving circuit 142 may be implemented as a chip, and the other driving circuit is formed on the TFT array substrate of the display device 400; or both the gate driving circuit 141 and the data driving circuit 142 may be formed on the TFT array substrate of the display device 400.

In addition, similar to the second embodiment, in another embodiment, the gate driving circuit 141 is disposed on the flexible circuit board, and the data driving circuit 142 is disposed in the non-display area 120; or the gate driving circuit 141 is disposed in the non-display area 120, and the data driving circuit 142 is disposed on the flexible circuit board; or the gate driving circuit 141 is disposed on one flexible circuit board, and the data driving circuit 142 is disposed on another flexible circuit board.

Similar to the first embodiment, in the embodiment, at least part of the first fan-out conductive lines FGL(1)-FGL(m) and at least part of the second fan-out conductive lines FDL(1)-FDL(n) belong to different conductive layers respectively. In addition, adjacent second fan-out conductive lines and/or adjacent first fan-out conductive lines are formed in different conductive layers. That is, the first fan-out conductive lines FGL(1)-FGL(m) and the second fan-out conductive lines FDL(1)-FDL(n) are formed in at least three different conductive layers.

### Fifth Embodiment

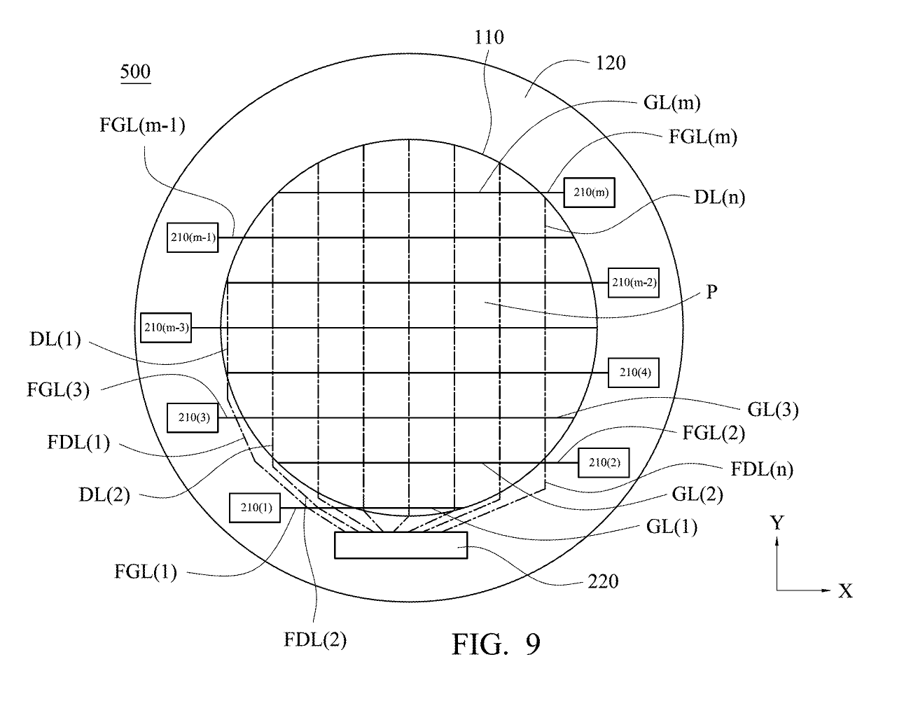

Referring to FIG. 9, FIG. 9 is a schematic diagram illustrating a top view of a display device 500 according to the fifth embodiment. In the embodiment of FIG. 9, gate driving circuits 210(1)-210(m) and a data driving circuit 220 are disposed in the non-display area 120. The gate driving circuits 210(1)-210(m) includes multiple TFTs, and the TFTs of the gate driving circuits 210(1)-210(m) and the TFTs T of the pixel structures P are formed on the TFT array substrate at the same time. The gate driving circuits 210(1)-210(m) are also referred to integrated gate drivers (IGD) or gate drivers on array (GOA). Each of the gate driving circuits 210(1)-210(m) includes a shift register circuit. The gate driving circuits 210(1), 210(3) . . . 210(m−1) and the gate driving circuits 212(2), 210(4) . . . 210(m) are disposed at two opposite sides of the display area 110. The gate driving circuits 210(1), 210(3) . . . 210(m−1) are electrically connected to odd gate lines GL(1), GL(3) . . . GL(m−1) in the display area 110 through odd first fan-out conductive lines FGL(1), FGL(3) . . . FGL(m−1). The gate driving circuits 210(2), 210(4) . . . 210(m) are electrically connected to even gate lines GL(2), GL(2) . . . GL(m) in the display area 110 through even first fan-out conductive lines FGL(2), FGL(4) . . . FGL(m). The data driving circuit 220 is disposed in the non-display area 120 below the display area 110. The data lines DL(1)-DL(n) in the display area 110 are electrically connected to the data driving circuit 220 through the second fan-out conductive lines FDL(1)-FDL(n) respectively. However, the numbers of and the disposition locations of the gate driving circuits 210(1)-210(m) and the data driving circuit 220 are not limited in the invention. It is noted that the gate driving circuits 210(1), 210(3) . . . 210(m−1) and the gate driving circuit 210(2), 210(4) . . . 210(m) are disposed at two opposite sides of the display area 110 in the embodiment of FIG. 9, but in another embodiment, all the gate driving circuits 210(1)-210(m) may be disposed at one side of the display area 110.

In the embodiment, the data driving circuit 220 may be implemented as a data driving chip or formed on the TFT array substrate of the display device 500, and the gate driving circuits 210(1)-210(m) are formed on the TFT array substrate of the display device 500. For example, the gate driving circuits 210(1)-210(m) include TFTs, and the TFTs of the gate driving circuits 210(1)-210(m) and the TFTs T of the pixel structures P are formed on the TFT array substrate by an amorphous silicon process or the low-temperature polysilicon process.

In the embodiment, at least part of the first fan-out conductive lines FGL(1)-FGL(m) and at least part of the second fan-out conductive lines FDL(1)-FDL(n) belong to different conductive layers respectively to prevent interlaced first fan-out conductive lines and second fan-out conductive lines from being shorted to each other. Furthermore, adjacent second fan-out conductive lines belong to different conductive layers to reduce the border width. That is, the first fan-out conductive lines FGL(1)-FGL(m) and the second fan-out conductive lines FDL(1)-FDL(n) are formed in at least three different conductive layers.

In the embodiment, the gate lines GL(1)-GL(m) extend toward the X-axis, and the gate driving circuits 210(1)-210(m) are respectively disposed at the locations corresponding to the gate lines GL(1)-GL(m) in the non-display area 120. Therefore, the first fan-out conductive lines FGL(1)-FGL(m) respectively extend toward the gate driving circuit 210(1)-210(m) along the X-axis, and thus the pitches of the first fan-out conductive lines FGL(1)-FGL(m) do not affect the border width. Accordingly, in the embodiment, the first fan-out conductive lines FGL(1)-FGL(m) preferably belong to the same conductive layer to reduce the manufacturing cost of the display device 500. However, the invention is not limited thereto, and adjacent first fan-out conductive lines may belong to different conductive layers.

Besides, in another embodiment, the data driving circuit 220 may be disposed on a flexible circuit board and electrically connected to bonding pads in the non-display area 120 through bonding leads on the flexible circuit board, and thus the data driving circuit 220 may provide a data signals to the pixel structures P in the display area 110.

### Sixth Embodiment

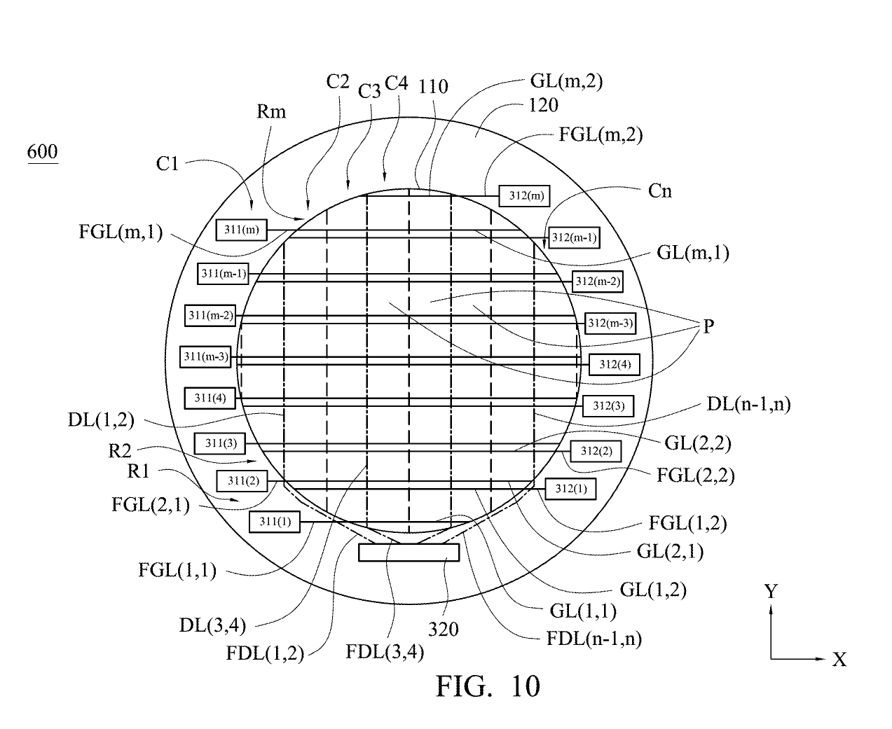

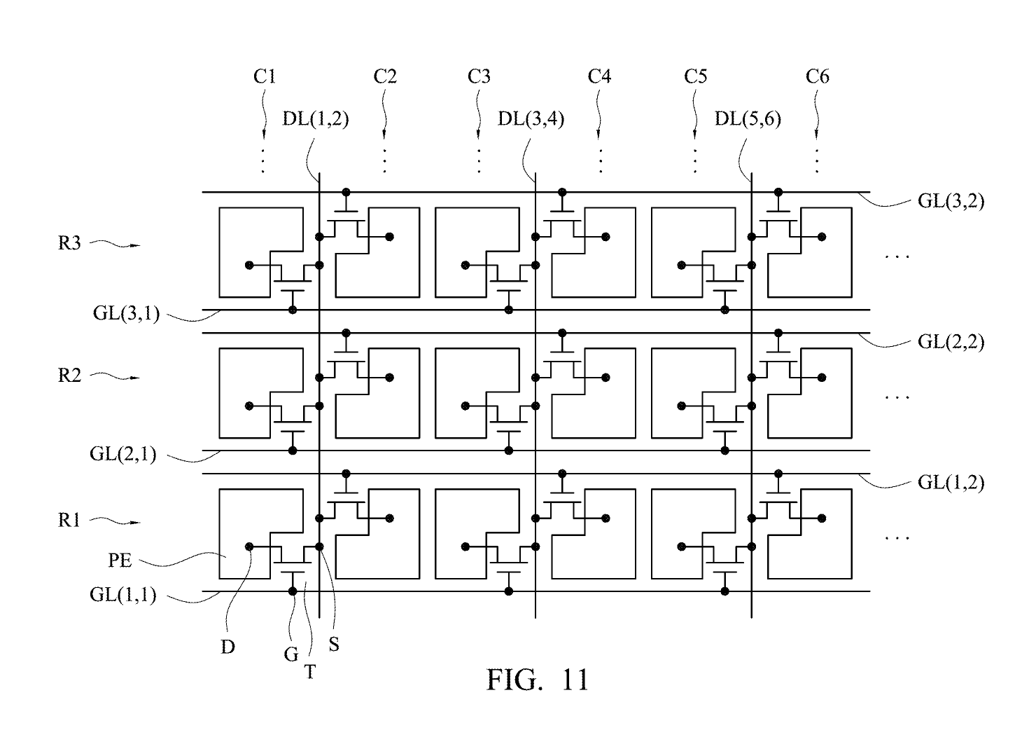

Referring to FIG. 10, FIG. 10 is a schematic diagram illustrating a top view of a display device 600 according to the sixth embodiment. In the embodiment of FIG. 10, multiple pixel structures P are disposed in the display area 110 (only three pixel structure P are labled as examples in FIG. 10), and the pixel structures are arranged as pixel rows R1-Rm and pixel columns C1-Cn. The display area 110 includes gate lines GL(1,1), GL(1,2), GL(2,1), GL(2,2) . . . GL(m,1), GL(m,2) and data lines DL(1,2)-DL(n−1,n). The difference between the embodiment of FIG. 10 and the embodiment of FIG. 9 is that each pixel row is coupled to two gate lines, and every two pixel columns share one data line (rest of FIG. 10 is similar to FIG. 9 and will not be repeated). For example, the gate lines GL(1,1), GL(1,2) are coupled to the pixel row R1, the gate lines GL(2,1), GL(2,2) are coupled to the pixel row R2, the pixel columns C1, C2 share the data line DL(1,2), and the pixel columns C3, C4 share the data line DL(3,4). Note that because there are two pixel columns between two adjacent data lines, the dash lines between adjacent data lines in FIG. 10 are used to label the boundary between two pixel columns. For example, the dash line between the data line DL(1,2) and DL(3,4) is used to label the boundary between the pixel columns C2 and C3. Referring to FIG. 10 and FIG. 11 together, FIG. 11 is a diagram illustrating an enlarged view of the pixel structures, the gate lines and the data lines in the display area 110 of FIG. 10. Each pixel structure P includes a TFT T and a pixel electrode PE connected to the TFT T. The gate G and source S of the TFT T are electrically connected to one of the gate lines GL(1,1)-GL(m,2) and one of the data lines DL(1,2)-DL(n,n−1) respectively. For example, the gate lines GL(1,1), GL(2,1), GL(3,1) are respectively coupled to the gates G of odd TFTs T in the pixel rows R1, R2 and R3. The gate lines GL(1,2), GL(2,2), GL(3,2) are respectively coupled to the gates G of even TFTs T in the pixel rows R1, R2 and R3. The data line DL(1,2) is coupled to the sources S of the TFTs T in the pixel columns C1 and C2. The data line DL(3,4) is coupled to the sources S of the TFTs T in the pixel columns C3 and C4. A design of double gate is adopted in the embodiments of FIG. 10 and FIG. 11. In other words, each pixel row is coupled to two gate lines, and two pixel columns share one data line. Compared to prior art, in which each pixel row and each pixel column are respectively coupled to one gate line and one data line, although the design of double gate in FIG. 10 and FIG. 11 increases the number of the gate lines, it decreases the number of the data lines. As shown in FIG. 10, the data driving circuit 320 is disposed in the non-display area 120 below the display area 110. The gate driving circuits 311(1)-311(m) and 312(1)-312(m) are disposed in the non-display area 120 at two opposite sides of the display area 110. Each of the gate driving circuits 311(1)-311(m) and 312(1)-312(m) includes a shift register circuit. The gate driving circuits 311(1)-311(m) are electrically connected to the gate lines GL(1,1), GL(2,1) . . . GL(m,1) through the first fan-out conductive lines FGL(1,1), FGL(2,1) . . . FGL(m,1) respectively. The gate driving circuits 312(1)-312(m) are electrically connected to the gate lines GL(1,2), GL(2,2) . . . GL(m,2) through the first fan-out conductive lines FGL(1,2), FGL(2,2) . . . FGL(m,2) respectively. One end of each of the second fan-out conductive lines FDL(1,2)-FDL(n−1,n) is electrically connected to corresponding one of the data lines DL(1,2)-DL(n−1,n), and the other end of each of the second fan-out conductive lines FDL(1,2)-FDL(n−1,n) is electrically connected to the data driving circuit 320.

Similar to the embodiment of FIG. 9, the gate lines GL(1,1)-GL(m,2) extend toward the X-axis, and the gate driving circuits 311(1)-311(m) and 312(1)-312(m) are disposed at the locations corresponding to the gate lines GL(1,1)-GL(m,2) respectively in the non-display area 120. Therefore, the first fan-out conductive lines FGL(1,1)-FGL(m,2) is capable of extending along the X-axis to electrically connect to the gate driving circuits 311(1)-311(m) and 312(1)-312(m). Hence, although the design of double gate in the embodiment increases the number of the gate lines, the width of the border is not increased. In addition, the width of the border is determined according to the number and the pitches of the fan-out conductive lines, and the design of double gate reduces the number of the data lines in half. Consequently, the width of the border is further decreased in the embodiment (compared to the embodiment of FIG. 9).

Similar to the embodiment of FIG. 9, in the embodiment, at least part of the first fan-out conductive lines FGL(1,1)-FGL(m,2) and at least part of the second fan-out conductive lines FDL(1,2)-FDL(n−1,n) belong to different conductive layers to prevent interlaced first fan-out conductive lines and second fan-out conductive lines from being shorted to each other. Adjacent second fan-out conductive lines belong to different conductive layers to reduce the width of the border. That is, the first fan-out conductive lines FGL(1)-FGL(m) and the second fan-out conductive lines FDL(1)-FDL(n) are formed in at least three different conductive layers. Furthermore, in the embodiment, the first fan-out conductive lines FGL(1,1)-FGL(m,2) are preferably belonging to the same conductive layer to reduce the manufacture cost of the display device 600. However, the invention is not limited thereto, and adjacent first fan-out conductive lines may belong to different conductive layers.

In addition, in another embodiment, the data driving circuit 320 may be disposed on a flexible circuit board and electrically connected to bonding pads in the non-display area 120 through bonding leads of the flexible circuit board. Therefore, the data driving circuit 320 can provide data signals to the pixel structures P in the display area 110.

The design of double gate in the embodiment may be applied to the first embodiment to the fifth embodiment. That is, the pixel structures, the gate lines and the data lines in the display area 110, and the first fan-out conductive lines and the second fan-out conductive lines in the non-display area 120 are replaced with the arrangement of the design of double gate in the embodiment, and the description thereof will be not be repeated.

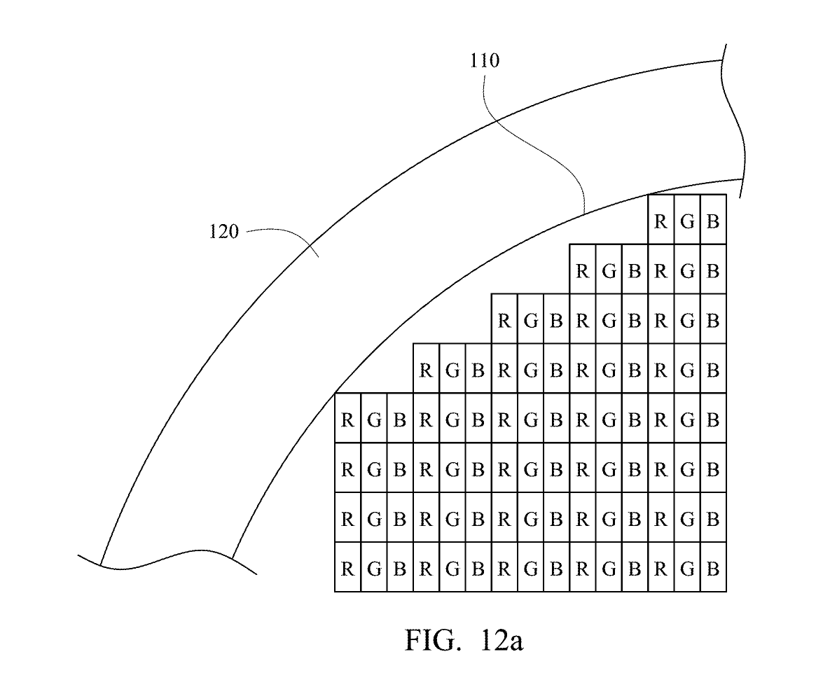

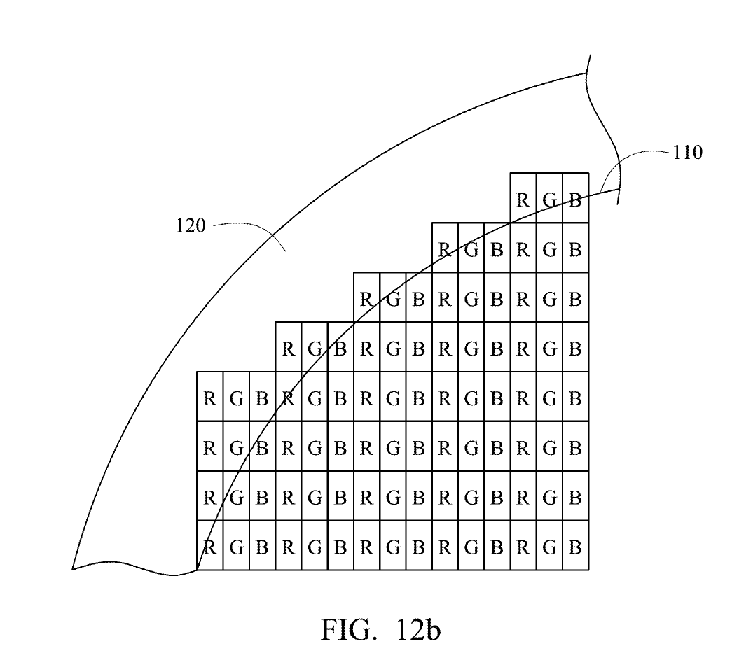

Note that the shape of the display area is non-rectangular and the shape of the pixel structures is rectangular in the invention, and therefore when the pixel structures are arranged in the non-rectangular display area, outer pixel structures may not be arranged along the contour of the display area. For example, referring to FIG. 12a and FIG. 12b, FIG. 12a and FIG. 12b are schematic diagrams illustrating part of the display device having a circle-shape display area 110. As shown in FIG. 12a, red/green/blue pixel structures R/G/B do not completely fill the display area 110. The red/green/blue pixel structures R/G/B fill the display area 110 in FIG. 12b and exceed the contour of the display area 110, and therefore some of the pixel structures are partially disposed in the display area 110 and partially disposed in the non-display area 120. In general, a shielding layer (e.g. black matrix (BM) layer) is disposed in the non-display area 120, and therefore the shape of the display area 110 of the display device in FIG. 12b is still circular. However, the arrangement of the pixel structures is not limited in the invention. In other words, both of the arrangement that the pixel structures do not completely fill the display area, and the arrangement that the pixel structures fill the display area and exceed the contour of the display area are included in the scope of the invention. Besides, the shape of the pixel structures is not limited in the invention. In another embodiment, the shape of the pixel structure may be hexagon, parallelogram, or other suitable shapes.

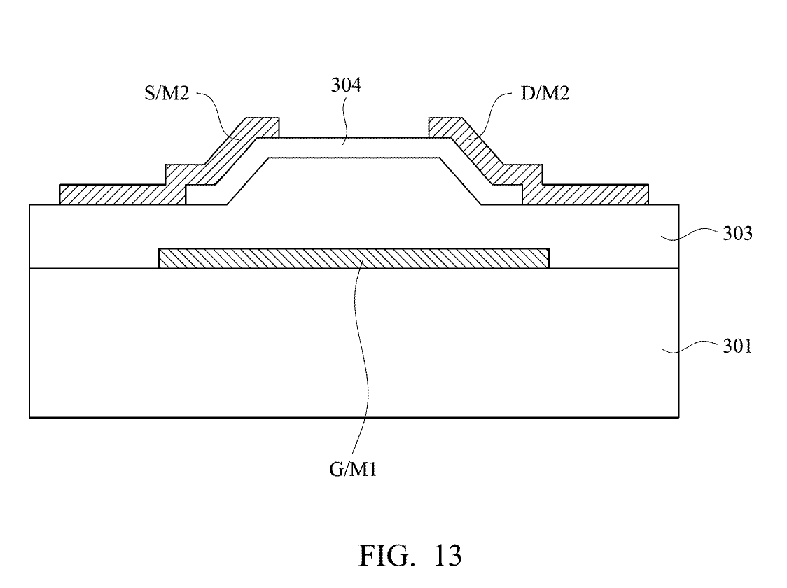

Referring to FIG. 13, FIG. 13 is a diagram illustrating a cross-sectional view of the thin film transistor T in the pixel structure P according to the first embodiment to the sixth embodiment. As shown in FIG. 13, the first metal layer M1 is formed on the substrate 301, and the first metal layer M1 includes the gate G of the TFT T. An insulating layer 303 is formed on the first metal layer M1. A semi-conductive layer 304 is formed on the insulating layer 303, and the semiconductor layer 304 is taken as a channel of the TFT T. The second metal layer M2 is formed on the semiconductor layer 304, and the second metal layer M2 includes a source S and a drain D of the TFT T. In other words, the first metal layer M1 is formed between the second metal layer M2 and the substrate 301.

Referring to FIG. 1 and FIG. 13 together, the gates G of the TFTs in the display area 110 belong to the first metal layer M1, and the gate lines GL(1)-GL(m) also belong to the first metal layer M1. However, the first fan-out conductive lines FGL(1)-FGL(m) in the non-display area 120 may not in the first metal layer (such as FIG. 3 and FIG. 5), and therefore it needs a connection structure to electrically connect different metal layers. Similarly, the sources S of the TFTs in the display area 110 belong to the second metal layer M2, and the data lines DL(1)-DL(n) also belong to the second metal layer M2. But, the second fan-out conductive lines FDL(1)-FDL(n) in the non-display area 120 may not be in the second metal layer M2 (such as FIG. 3 and FIG. 5), and therefore it needs the connection structure to electrically connect different metal layers. Several embodiments will be provided to describe the connection structures.

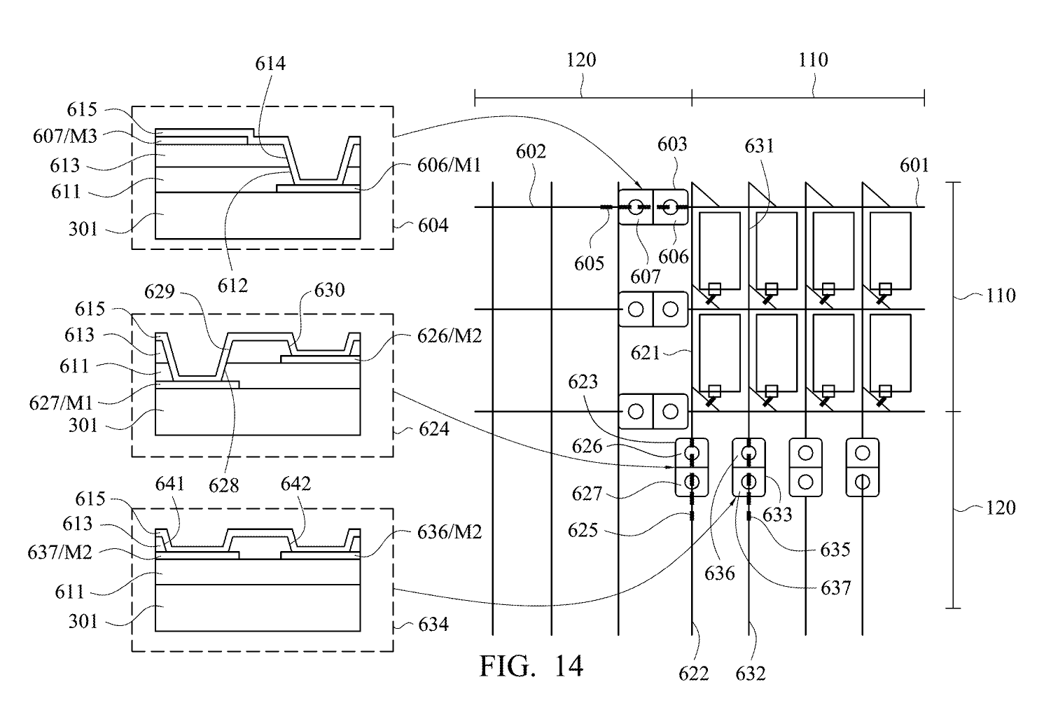

Referring to FIG. 14, FIG. 14 is a schematic diagram illustrating the connection structures according to the first embodiment to the sixth embodiment. The first fan-out conductive lines and the second fan-out conductive lines are implemented by the embodiment of FIG. 5. That is, the first fan-out conductive lines belong to the third metal layer M3, and adjacent second fan-out conductive lines respectively belong to the first metal layer M1 and the second metal layer M2. There are three different connection structures in FIG. 14 which will be described below.

First, the display area 110 includes a gate line 601, and the non-display area 120 includes a first fan-out conductive line 602. The first fan-out conductive line 602 includes a first portion 606 and a second portion 607. The first portion 606 belongs to the first metal layer M1 and is coupled to the gate line 601 belonging to the first metal layer M1. The second portion 607 belongs to the third metal layer M3. A connection structure 603 is disposed on the first fan-out conductive line 602 for electrically connecting the first portion 606 to the second portion 607. A structure 604 illustrates a cross-sectional view of the connection structure 603 along a section line 605. To be specific, the first metal layer M1 is on the substrate 301, and a first insulating layer 611 is on the first metal layer M1. The first insulating layer 611 includes an opening 612 to expose the first portion 606. A second insulating layer 613 is on the first insulating layer 611, and the second insulating layer 613 includes an opening 614 which is corresponding to the opening 612. The third metal layer M3 is formed on the second insulating layer 613, and the third metal layer M3 includes the second portion 607 of the first fan-out conductive line 602. A conducting layer 615 is on the third metal layer M3, and is electrically connected to the second portion 607, and is electrically connected to the first portion 606 through the opening 614 and the opening 612. That is, the conducting layer 615 bridges the first portion 606 and the second portion 607. As a result, the first portion 606 in the first metal layer M1 is electrically connected to the second portion 607 in the third metal layer M3. In some embodiments, material of the conducting layer 615 includes transparent conductive material such as indium tin oxide (ITO), indium zinc oxide (IZO) or other conductive material.

Second, the display area 110 includes a data line 621, and the non-display area 120 includes a second fan-out conductive line 622. The second fan-out conductive line 622 includes a first portion 626 and a second portion 627. The first portion 626 belongs to the second metal layer M2 and is coupled to the data line 621 belonging to the second metal layer M2. The second portion 627 belongs to the first metal layer M1. A connection structure 623 is disposed on the second fan-out conductive line 622 for electrically connecting the first portion 626 to the second portion 627. A structure 624 illustrates a cross-sectional view of the connection structure 623 along a section line 625. To be specific, in the structure 624, the first insulating layer 611 includes an opening 628 to expose the second portion 627. The second metal layer M2 is formed on the first insulating layer 611, and the second insulating layer 613 is formed on the second metal layer M2. The second insulating layer 613 includes openings 629 and 630. The opening 629 is corresponding to the opening 628, and the opening 630 is used to expose the first portion 626. The conducting layer 615 is electrically connected to the first portion 626 through the opening 630, and is electrically connected to the second portion 627 through the openings 629 and 628. As a result, the first portion 626 in the second metal layer M2 is electrically connected to the second portion 627 in the first metal layer M1.

Third, the display area 110 further includes a data line 631 which is adjacent to the data line 621. The non-display area 120 further includes a second fan-out conductive line 632 which is adjacent to the second fan-out conductive line 622. The second fan-out conductive line 632 includes a first portion 636 and a second portion 637. Both of the first portion 636 and the second portion 637 belong to the second metal layer M2, and the first portion 636 is coupled to the data line 631 belonging to the second metal layer M2. A connection structure 633 is disposed on the second fan-out conductive line 632 for electrically connecting the first portion 636 to the second portion 637. A structure 634 illustrates a cross-sectional view of the connection structure 633 along a section line 635. To be specific, in the structure 634, the second insulating layer 613 includes an opening 641 and an opening 642 which respectively expose the second portion 637 and the first portion 636. The conducting layer 615 is electrically connected to the second portion 637 through the opening 641, and is electrically connected to the first portion 636 through the opening 642. Note that although both of the data line 631 and the second fan-out conductive line 632 belong to the second metal layer M2, the first portion 636 and the second portion 637 belonging to the second metal layer M2 are electrically connected through the conducting layer 615 to achieve resistance match with the second fan-out conductive lines 622 because the connection structure 623 is disposed on the second fan-out conductive line 622, which is adjacent to the second fan-out conductive line 632, for bridging different metal layers through the conducting layer 615.

The manufacturing process of the embodiment is provided as follows. The first metal layer, the second metal layer, the third metal layer and a transparent conductive layer are sequentially formed on the substrate. The first metal layer and the second metal layer are also used to form the gates and the drains/sources of the TFTs except for forming the gate lines, the data lines and the fan-out conductive lines. The transparent conductive layer is used to bridge different metal layers, and also used to form a common electrode or a pixel electrode of the display device.

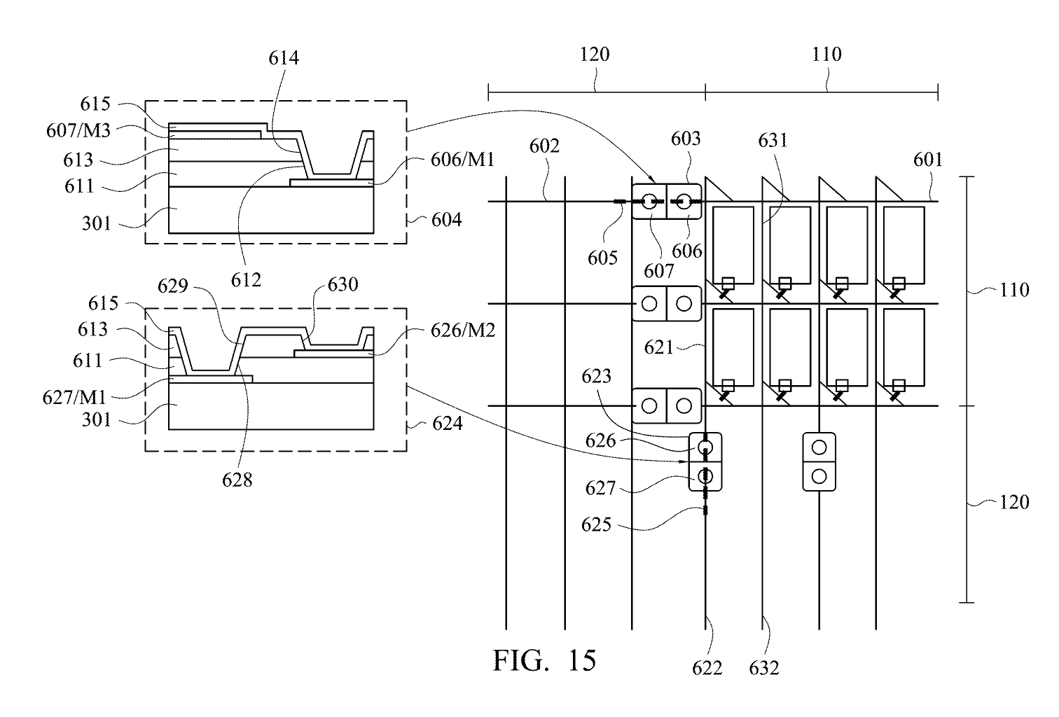

Note that in some embodiments, as shown in FIG. 15, the data line 631 belonging to the second metal layer M2 is directly connected to the second fan-out conductive line 632 belonging to the second metal layer M2 without disposing the connection structure 633.

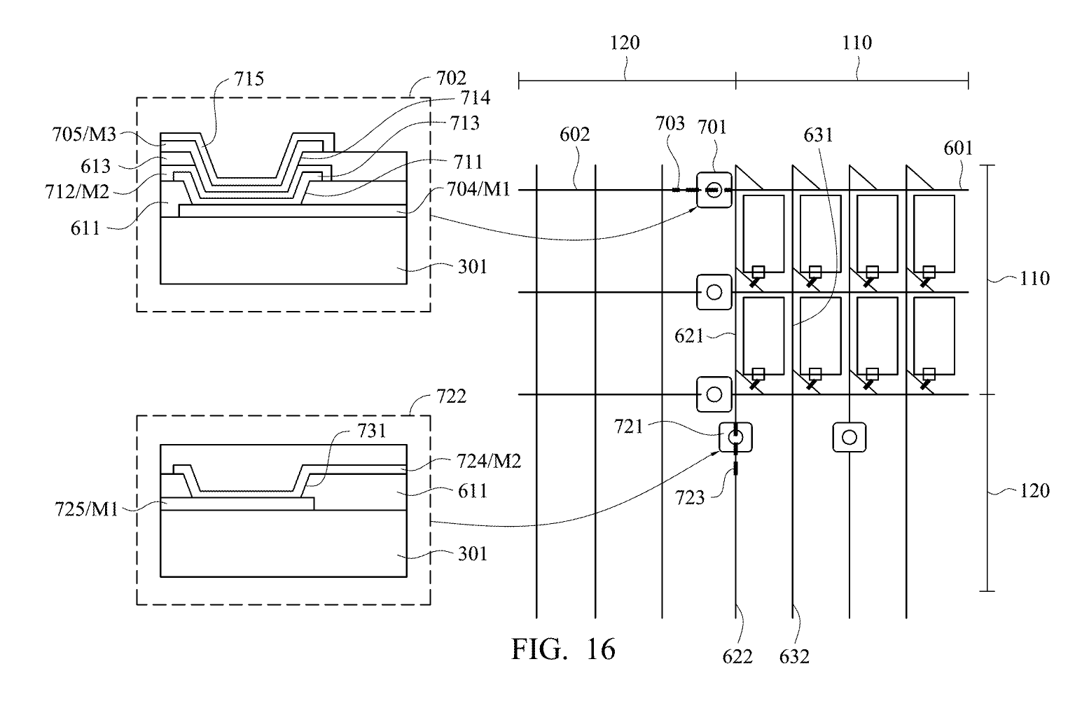

Referring to FIG. 16, FIG. 16 is a schematic diagram illustrating another connection structure according to the first embodiment to the sixth embodiment. The first fan-out conductive lines and the second fan-out conductive lines are implemented by the embodiment of FIG. 5. In FIG. 14, the conducting layer 615 bridges different metal layers M1 and M3 in the connection structure 603, and the conducting layer 615 bridges different metal layer M1 and M2 in the connection structure 623. However, different from FIG. 14, different metal layers are electrically connected by filling a metal layer into the openings of the insulating layer in the connection structure in FIG. 16. Rest of FIG. 16 is similar to the embodiment of FIG. 14, and only the difference between FIG. 14 and FIG. 16 will be described.

The first fan-out conductive line 602 includes a first portion 704 and a second portion 705. The first portion 704 belongs to the first metal layer M1 and is coupled to the gate line 601 belonging to the same first metal layer M1. The second portion 705 belongs to the third metal layer M3. A connection structure 701 is disposed on the first fan-out conductive line 602. A structure 702 illustrates a cross-sectional view of the connection structure 701 along a section line 703. To be specific, the first insulating layer 611 includes an opening 711 to expose the first portion 704. The first conducting layer 713 is electrically connected to the first portion 704 through the opening 711. A metal pad 712 belongs to the second metal layer M2, and the metal pad 712 is formed on the first conducting layer 713 and is electrically connected to the first conducting layer 713. The first conducting layer 713 is used to protect the first portion 704 when patterning the second metal layer M2 to form the metal pad 712. However, in some embodiments, the first conducting layer 713 may be omitted, and the invention is not limited thereto. The second insulating layer 613 is formed on the metal pad 712 and includes an opening 714 which is corresponding to the opening 711. The second portion 705 is electrically connected to the metal pad 712 through the opening 714, and is thus electrically connected to the first conducting layer 713 and the first portion 704. That is, the first portion 704, the metal pad 712 and the second portion 705 are stacked on the substrate 301, and the first portion 704, the metal pad 712 and the second portion 705 are electrically connected to each other. In some embodiments, a second conducting layer 715 is formed on the third metal layer M3 to cover the second portion 705. The material of the first conducting layer 713 and the second conducting layer 715 includes transparent conductive material such as ITO, IZO or other conductive material. The second conducting layer 715 is used to protect the second portion 705, but the second conducting layer 715 may be omitted in some embodiments, and the invention is not limited thereto.

The second fan-out conductive line 622 includes a first portion 724 belonging to the second metal layer M2 and a second portion 725 belonging to the first metal layer M1. The first portion 724 is coupled to the data line 621 belonging to the second metal layer M2. A connection structure 721 is disposed on the second fan-out conductive line 622 for electrically connecting the first portion 724 to the second portion 725. A structure 722 illustrates a cross-sectional view of the connection structure 721 along a section line 723. In the structure 722, the first insulating layer 611 includes an opening 731 to expose the second portion 725. The first portion 724 is electrically connected to the second portion 725 through the opening 731.

In the embodiment, resistance of the connection structure 721 is very low compared to the connection structure 623 of FIG. 14 in which the conducting layer 615 is electrically connected to different metal layers because different metal layers are connected to each other through the opening 731 of the first insulating layer 611 in the connection structure 721. Since the resistance of the connection structure 721 is very low, the data line 631 is directly connected to the second fan-out conductive line 632 in the second metal layer M2 without disposing additional connection structure on the second fan-out conductive line 632.

The manufacturing process of the embodiment is provided as follows. The first metal layer, a first transparent conductive layer, the second metal layer, the third metal layer and a second transparent conductive layer are formed on the substrate. The first metal layer and the second metal layer are also used to form the gates and the drains/sources of the TFTs except for forming the gate lines, the data lines and the fan-out conductive lines. The first transparent conductive layer also forms the pixel electrodes of the display device except for electrically connecting the first metal layer and the second metal layer in connection structure. The second transparent conductive layer is also used to form the common electrodes of the display device except for protecting part of the first fan-out conductive line.

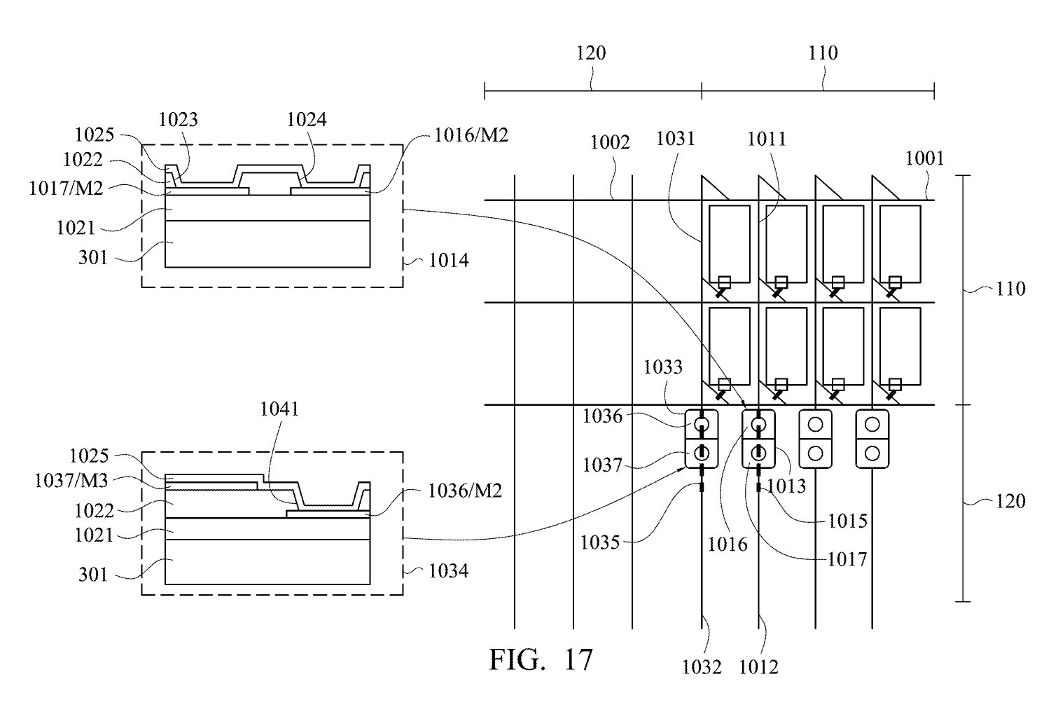

Referring to FIG. 17, FIG. 17 is a schematic diagram illustrating a connection structure according to the first embodiment to the sixth embodiment. The first fan-out conductive lines and the second fan-out conductive lines are implemented by the embodiment of FIG. 4. That is, the first fan-out conductive lines belong to the first metal layer M1, and adjacent second fan-out conductive lines respectively belong to the second metal layer M2 and the third metal layer M3.

In the embodiment, the display area 110 includes a data line 1031 which is adjacent to a data line 1011. The non-display area 120 includes a second fan-out conductive line 1032 which is adjacent to a second fan-out conductive line 1012. The data lines 1031 and 1011, and the second fan-out conductive line 1012 belong to the second metal layer M2. At least part of the second fan-out conductive line 1032 belongs to the third metal layer M3. The second fan-out conductive line 1032 includes a first portion 1036 belonging to the second metal layer M2, and a second portion 1037 belonging to the third metal layer M3. The first portion 1036 is coupled to the data line 1031 belonging to the second metal layer M2. A connection structure 1033 is disposed on the second fan-out conductive line 1032 for electrically connecting the first portion 1036 to the second portion 1037. A structure 1034 illustrates a cross-sectional view of the connection structure 1033 along a section line 1035. To be specific, in the structure 1034, a first insulating layer 1021 is formed on the substrate 301. The second metal layer M2 is formed on the first insulating layer 1021. A second insulating layer 1022 is formed on the second metal layer M2, and the second insulating layer 1022 includes an opening 1041 to expose the first portion 1036. The third metal layer M3 is formed on the second insulating layer 102. A conducting layer 1025 is electrically connected to the second portion 1037, and is electrically connected to the first portion 1036 through the opening 1041. Material of the conducting layer 1025 includes transparent conductive material such as ITO, IZO or other conductive material.

Similar to the embodiment of FIG. 14, both of the data line 1011 and the second fan-out conductive line 1012 belong to the second metal layer M2, but the connection structure 1013 is still disposed on the second fan-out conductive line 1012 for the resistance match. The second fan-out conductive line 1012 includes a first portion 1016 and a second portion 1017, and both of them belong to the second metal layer M2. The first portion 1016 is coupled to the data line 1011 belonging to the second metal layer M2. A connection structure 1013 is used to couple the first portion 1016 to the second portion 1017. A structure 1014 illustrates a cross-sectional view of the connection structure 1013 along a section line 1015. To be specific, in the structure 1014, the first insulating layer 1021 is formed on the substrate 301, the second metal layer M2 is formed on the first insulating layer 1021, and the second metal layer M2 includes the first portion 1016 and the second portion 1017. The second insulating layer 1022 is formed on the second metal layer M2, and the second insulating layer 1022 includes an opening 1023 and an opening 1024, in which the opening 1023 exposes the second portion 1017, and the opening 1024 exposes the first portion 1016. The conducting layer 1025 is formed on the second insulating layer 1022, and is electrically connected to the second portion 1017 through the opening 1023, and is electrically connected to the first portion 1016 through the opening 1024.

In the embodiment, both of a gate line 1001 and a first fan-out conductive line 1002 belong to the first metal layer M1, and therefore they do not need a connection structure.

Similar to the embodiment of FIG. 15, the data line 1011 belonging to the second metal layer M2 is directly connected to the second fan-out conductive line 1012 belonging to the second metal layer M2 in another embodiment, and therefore the connection structure 1013 is not required.

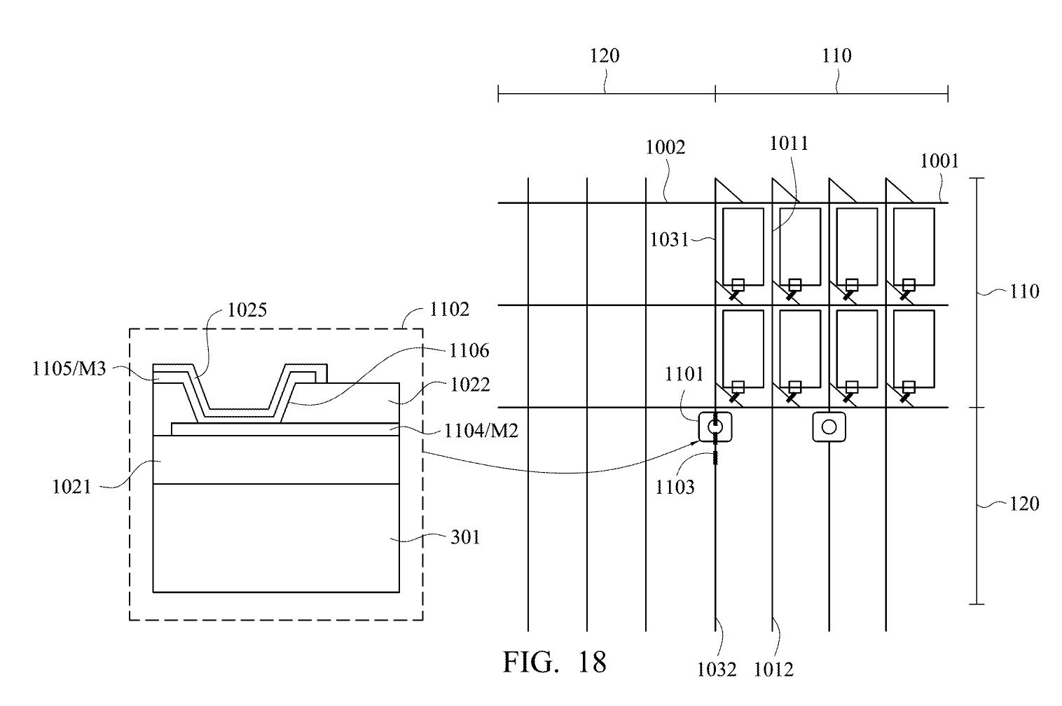

Referring to FIG. 18, FIG. 18 is a schematic diagram illustrating another connection structure according to the first embodiment to the sixth embodiment. The first fan-out conductive lines and the second fan-out conductive lines are implemented by the embodiment of FIG. 4. In FIG. 17, the conducting layer 1025 bridges different metal layers M2 and M3 in the connection structure 1033. However, different from FIG. 17, different metal layers are electrically connected by filling a metal layer into an opening of an insulating layer in the connection structure in FIG. 18. Rest of FIG. 18 is similar to the embodiment of FIG. 17, and therefore only the difference between FIG. 17 and FIG. 18 will be described.

A connection structure 1101 is disposed on the second fan-out conductive line 1032. The second fan-out conductive line 1032 includes a first portion 1104 belonging to the second metal layer M2 and a second portion 1105 belonging to the third metal layer M3. The first portion 1104 is coupled to the data line 1031. A structure 1102 illustrates a cross-sectional view of the connection structure 1101 along a section line 1103. To be specific, in the structure 1102, the first insulating layer 1021 is formed on the substrate 301, the second metal layer M2 is formed on the first insulating layer 1021. The second insulating layer 1022 is formed on the second metal layer M2 and includes an opening 1106 which exposes the first portion 1104. The third metal layer M3 is formed on the second insulating layer 1022. The second portion 1105 is electrically connected to the first portion 1104 through the opening 1106. The conducting layer 1025 covers the second portion 1105 to protect the second portion 1105. However, the conducting layer 1025 is omitted in some embodiments, and the invention is not limited thereto.

In the embodiment, different metal layers M2 and M3 are directly electrically connected through the opening 1106 of the second insulating layer 1022 in the connection structure 1101, and thus the connection structure 1101 has lower resistance compared to the connection structure 1033 in FIG. 17 in which different metal layers are electrically connected through the conducting layer 1025. Because the connection structure 1101 has lower resistance, the data line 1011 and the second fan-out conductive line 1012, which are both belonging to the second metal layer M2, are connected to each other directly, and no additional connection structure is disposed on the second fan-out conductive line 1012.

Note that in the embodiment of FIG. 3, the second fan-out conductive lines FDL(i−2), FDL(i) and FDL(i+2) belong to the first metal layer M1, the second fan-out conductive lines FDL(i−1), FDL(i+1) and FDL(i+3) belong to the second metal layer M2, the first fan-out conductive lines FGL(j−2), FGL(j) and FGL(j+2) belong to the third metal layer M3, and the first fan-out conductive lines FGL(j−1) and FGL(j+1) belong to the fourth metal layer M4. Therefore, connection structures are disposed on the second fan-out conductive line FDL(i−2), FDL(i) and FDL(i+2) to electrically connect the first metal layer M1 to the second metal layer M2. Connection structures are also disposed on the first fan-out conductive line FGL(j−2), FGL(j) and FGL(j+2) to electrically connect the first metal layer M1 to the third metal layer M3. Furthermore, connection structures are disposed on the first fan-out conductive line FGL(j−1) and FGL(j+1) to electrically connect the first metal layer M1 to the fourth metal layer M4. People in the art should be able to modify the disclosure of FIG. 14 to FIG. 18 to design the connection structures suitable for FIG. 3.

In the display device provided by the embodiments of the disclosure, the first fan-out conductive lines and the second fan-out conductive line in the non-display area are formed in at least three different conductive layers. Therefore, the first fan-out conductive lines and the second fan-out conductive lines are prevented from be shorted to each other, and the pitches of the second fan-out conductive lines and/or the first fan-out conductive lines are reduced, and thus the border of the display device is narrowed.

Although the present invention has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. A display device, comprising:
a display area and a non-display area, wherein a shape of the display area is non-rectangular;
a plurality of pixel structures disposed in the display area, wherein the pixel structures are disposed on a substrate and arranged as a plurality of pixel rows and a plurality of pixel columns;
a plurality of gate lines and a plurality of data lines disposed in the display area, wherein the gate lines are coupled to the pixel rows, and the data lines are coupled to the pixel columns;
a plurality of first fan-out conductive lines disposed in the non-display area, wherein the first fan-out conductive lines are coupled to the gate lines;
a plurality of second fan-out conductive lines disposed in the non-display area, wherein the second fan-out conductive lines are coupled to the data lines; and
at least one driving circuit coupled to the first fan-out conductive lines and the second fan-out conductive lines,
wherein the first fan-out conductive lines and the second fan-out conductive lines are formed in at least three different conductive layers.

2. The display device of claim 1, wherein at least one of the first fan-out conductive lines belongs to a first conductive layer, two adjacent ones of the second fan-out conductive lines are respectively belong to a second conductive layer and a third conductive layer, and the first conductive layer, the second conductive layer and the third conductive layer are different from each other.

3. The display device of claim 2, wherein the first conductive layer is a first metal layer, the second conductive layer is a second metal layer, and the third conductive layer is a third metal layer,
wherein the second metal layer is formed at a side of the first metal layer opposite to the substrate, and the third metal layer is formed at a side of the second metal layer opposite to the first metal layer.

4. The display device of claim 2, wherein the first conductive layer is a third metal layer, the second conductive layer is a first metal layer, and the third conductive layer is a second metal layer,
wherein the second metal layer is formed at a side of the first metal layer opposite to the substrate, and the third metal layer is formed at a side of the second metal layer opposite to the first metal layer.

5. The display device of claim 4, wherein two adjacent ones of the first fan-out conductive lines are respectively belong to the third metal layer and a fourth metal layer, and the fourth metal layer is formed at a side of the third metal layer opposite to the second metal layer.

6. The display device of claim 1, wherein the at least one driving circuit comprises a gate driving circuit and a data driving circuit, and at least one of the gate driving circuit and the data driving circuit is disposed in the non-display area.

7. The display device of claim 1, wherein the at least one driving circuit is disposed on at least one flexible circuit board, and the at least one flexible circuit board is connected to the first fan-out conductive lines and the second fan-out conductive lines.

8. The display device of claim 1, wherein each of the gate lines is electrically connected to one of the pixel rows, and each of the data lines is electrically connected to one of the pixel columns.

9. The display device of claim 1, wherein two adjacent ones of the gate lines are electrically connected to one of the pixel rows, and each of the data lines is electrically connected to two adjacent ones of the pixel columns.

10. The display device of claim 8, wherein the at least one driving circuit comprises a plurality of gate driving circuits and a data driving circuit, the gate driving circuits are disposed in the non-display area, each of the first fan-out conductive lines is electrically connected to one of the gate driving circuits, and the second fan-out conductive lines are electrically connected to the data driving circuit.

11. The display device of claim 9, wherein the at least one driving circuit comprises a plurality of gate driving circuits and a data driving circuit, the gate driving circuits are disposed in the non-display area, each of the first fan-out conductive lines is electrically connected to one of the gate driving circuits, and the second fan-out conductive lines are electrically connected to the data driving circuit.

12. The display device of claim 1, wherein one of the pixel structures is partially disposed in the display area and partially disposed in the non-display area.

13. The display device of claim 3, wherein at least one of the second fan-out conductive lines comprises a first portion belonging to the second metal layer and a second portion belonging to the third metal layer,
wherein an insulating layer is formed between the second metal layer and the third metal layer, and the insulating layer comprises an opening exposing the first portion,
wherein the first portion and the second portion are electrically connected to each other through a conducting layer, and the conducting layer directly contacts the second portion and directly contacts the first portion through the opening.

14. The display device of claim 13, wherein material of the conducting layer is transparent conductive material.

15. The display device of claim 13, wherein another second fan-out conductive line adjacent to the at least one second fan-out conductive line comprises a third portion and a fourth portion, both of the third portion and the fourth portion belong to the second metal layer, the insulating layer comprises a second opening to expose the third portion and a third opening to expose the fourth portion, and the third portion is electrically connected to the fourth portion through the conducting layer, wherein the conducting layer directly contacts the third portion through the second opening and directly contacts the fourth portion through the third opening.

16. The display device of claim 3, wherein at least one of the second fan-out conductive lines comprises a first portion belonging to the second metal layer and a second portion belonging to the third metal layer,
wherein an insulating layer is formed between the second metal layer and the third metal layer, and the insulating layer comprises an opening exposing the first portion, and the second portion is electrically connected to the first portion through the opening.

17. The display device of claim 4, wherein at least one of the second fan-out conductive lines comprises a first portion belonging to the second metal layer and a second portion belonging to the first metal layer,
wherein an insulating layer is formed between the second metal layer and the third metal layer, and the insulating layer comprises an opening exposing the second portion,
wherein the first portion and the second portion are electrically connected to each other by a conducting layer, and the conducting layer directly contacts the first portion and directly contacts the second portion through the opening.

18. The display device of claim 4, wherein at least one of the first fan-out conductive lines comprises a first portion belonging to the first metal layer and a second portion belonging to the third metal layer,
wherein a first insulating layer and a second insulating layer are formed between the first metal layer and the third metal layer, the first insulating layer comprises a first opening exposing the first portion, and the second insulating layer comprises a second opening corresponding to the first opening,
wherein the first portion and the second portion are electrically connected to each other through a conducting layer, and the conducting layer directly contacts the second portion and directly contacts the first portion through the first opening and the second opening.

19. The display device of claim 4, wherein at least one of the second fan-out conductive lines comprises a first portion belonging to the second metal layer and a second portion belonging to the first metal layer,
wherein an insulating layer is formed between the first metal layer and the second metal layer, the insulating layer comprises an opening exposing the second portion, and the first portion is electrically connected to the second portion through the opening.

20. The display device of claim 4, wherein at least one of the first fan-out conductive lines comprises a first portion belonging to the first metal layer and a second portion belonging to the third metal layer, and a metal pad belonging to the second metal layer is formed between the first portion and the second portion,
wherein the first portion, the metal pad and the second portion are stacked on the substrate, and the first portion, the metal pad and the second portion are electrically connected to each other.
